(19) United States
(12) Patent Application Publication
(10) Pub. No.: US 2025/0374654 A1
(43) Pub. Date: Dec. 4, 2025

(54) SEMICONDUCTOR DEVICES INCLUDING SELF-ALIGNED BACKSIDE CONTACT STRUCTURES AND METHODS FOR FABRICATING THE SAME

(71) Applicant: Samsung Electronics Co., Ltd., Suwon-si (KR)

(72) Inventors: Joongsuk Oh, Watervliet, NY (US); Inwon Park, Niskayuna, NY (US); Byounghoon Kim, Rexford, NY (US); Kang-ill Seo, Springfield, VA (US)

(21) Appl. No.: 18/953,690

(22) Filed: Nov. 20, 2024

Related U.S. Application Data
(60) Provisional application No. 63/652,754, filed on May 29, 2024.

(51) Int. Cl. H01L 21/8234; H01L 23/528; H01L 27/088; H01L 29/06; H01L 29/08; H01L 29/423; H01L 29/66; H01L 29/775; H01L 29/786

(52) U.S. Cl. CPC H10D 84/038; H01L 23/5286; H10D 30/014; H10D 30/43; H10D 30/6735; H10D 30/6757; H10D 62/121; H10D 62/151; H10D 84/0128; H10D 84/013; H10D 84/0149; H10D 84/83

(57) ABSTRACT

A method of fabricating a semiconductor device includes forming capping patterns that are spaced apart from each other in a first direction at a first side of a semiconductor structure, and forming channel structures and source/drain regions therebetween that are spaced apart from each other in the first direction at a second side of the semiconductor structure that is opposite the first side of the semiconductor structure. The capping patterns overlap the channel structures in the second direction, respectively. The method further includes forming a backside contact structure that is electrically connected to at least one of the source/drain regions and is aligned to overlap the at least one of the source/drain regions in the second direction based on the capping patterns.

### RELATED APPLICATIONS

The present application claims the benefit of U.S. Provisional Patent Application Ser. No. 63/652,754, entitled “INTEGRATED CIRCUIT DEVICES INCLUDING BACKSIDE POWER DISTRIBUTION NETWORK WITH SELF-ALIGNED BACKSIDE CONTACT AND METHOD OF FORMING THE SAME,” filed on May 29, 2024, with the United States Patent and Trademark Office, the disclosure of which is hereby incorporated by reference herein in its entirety.

### TECHNICAL FIELD

The present disclosure generally relates to the field of semiconductor devices and, more particularly, to integrated circuit devices having backside contacts.

### BACKGROUND

Integrated circuit (IC) devices, chips, and/or blocks may receive power and data signals from one or more external sources (e.g., a power source and a data source). Some IC devices may receive power and data signals via frontside conductive structures, which may provide power distribution networks (PDNs). For example, an IC device may include a frontside power distribution network (FSPDN) having one or more components that are formed during back-end- of-line (BEOL) processes, and conductive structures for data signals may be on the same side of an IC device as the FSPDN. IC devices may include various transistor structures, including, for example, two-dimensional (2D) planar structures, fin field-effect transistors (FinFETs), gate-all-around transistors, multi-bridge channel FETs (MBCFETs™), and stacked transistors (e.g., three-dimensional (3D) stacked transistors).

More recently, backside PDNs (BSPDNs), in which a backside of an IC device is used as a PDN, have also been developed. In a BSPDN structure, a power rail may be formed on the backside of a semiconductor chip, IC device, or wafer (generally referred to herein as a semiconductor device), rather than on the frontside thereof. As such, the power rail may be on a side of the semiconductor structure (e.g., a side of a substrate of the IC device) that is opposite from the active components (e.g., transistors) of the IC device. Moreover, conductive structures for data signals may be on the frontside of the semiconductor device, and thus the BSPDN and the conductive structures for the data signals may be on opposite sides of the semiconductor device. BSPDN structures may improve power rail effectiveness, voltage drop (i.e., IR drop), high power delivery performance, and further scaling of standard cell height.

### SUMMARY

According to some embodiments, a semiconductor device includes a substrate, source/drain regions with channel structures extending therebetween at a first side of the substrate, wherein the source/drain regions are spaced apart from each other in a first direction by the channel structures, and a backside contact structure extending into a second side of the substrate that is opposite the first side of the substrate, wherein the backside contact structure is electrically connected to at least one of the source/drain regions. The backside contact structure includes a lower contact structure and an upper contact structure between the lower contact structure and the at least one of the source/drain regions, and the respective side surfaces of the upper contact structure and the lower contact structure have different slopes. The upper contact structure has a first width adjacent the at least one of the source/drain regions and a second width adjacent the lower contact structure, and the second width is greater than the first width.

In some embodiments, the respective side surfaces of the upper contact structure and the lower contact structure define a step difference therebetween.

In some embodiments, a first slope of the side surface of the upper contact structure is less than a second slope of the side surface of the lower contact structure.

In some embodiments, a width of the upper contact structure continuously decreases from the second width to the first width as the upper contact structure extends from the lower contact structure to the at least one of the source/drain regions.

In some embodiments, semiconductor device further includes etch stop layers at the first side of the substrate, wherein the etch stop layers are on the source/drain regions, respectively. The backside contact structure extends through at least one of the etch stop layers to contact the at least one of the source/drain regions.

In some embodiments, the etch stop layers have an etch selectivity to the source/drain regions, and the backside contact structure does not overlap at least one of the etch stop layers in a second direction that is perpendicular to the first direction.

In some embodiments, the semiconductor device further includes a backside power distribution network structure on a lower surface of the substrate. The lower surface of the substrate is at the second side of the substrate, and the backside contact structure electrically connects the backside power distribution network structure to at least one of the source/drain regions.

According to some embodiments, a method of fabricating a semiconductor device includes forming capping patterns that are spaced apart from each other in a first direction at a first side of a semiconductor structure and forming channel structures and source/drain regions therebetween that are spaced apart from each other in the first direction at a second side of the semiconductor structure that is opposite the first side of the semiconductor structure. The capping patterns overlap the channel structures in the second direction, respectively. The method further includes forming a backside contact structure that is electrically connected to at least one of the source/drain regions and is aligned to overlap the at least one of the source/drain regions in the second direction based on the capping patterns.

In some embodiments, opposing side surfaces of the capping patterns are substantially aligned with opposing side surfaces of the channel structures, respectively, in the second direction.

In some embodiments, forming the backside contact structure includes forming a placeholder on at least one of the source/drain regions. The placeholder extends into the second side of the semiconductor structure between adjacent ones of the capping patterns.

In some embodiments, forming the placeholder includes forming an opening between the adjacent ones of the capping patterns in the semiconductor structure that overlaps with at least one of the source/drain regions in the second direction and forming the placeholder in the opening. At least some of the source/drain regions are free of overlap with respective placeholders in the second direction.

In some embodiments, forming the backside contact structure further includes removing the semiconductor structure and the capping patterns therein to expose the placeholder, forming a substrate on the placeholder, the channel structures, and the source/drain regions, wherein the channel structures and the source/drain regions are at a first side of the substrate, patterning a second side of the substrate that is opposite the first side of the substrate in the second direction to form a first opening therein that exposes the placeholder, and replacing the placeholder with the backside contact structure.

In some embodiments, replacing the placeholder includes removing the placeholder to form a second opening in the substrate that is coupled to the first opening and forming the backside contact structure in the first opening and the second opening.

In some embodiments, respective side surfaces of the first opening and the second opening have different slopes, and the backside contact structure includes a lower contact structure in the first opening and an upper contact structure in the second opening between the lower contact structure and at least one of the source/drain regions.

In some embodiments, the respective side surfaces of the first opening and the second opening define a step difference therebetween.

In some embodiments, the method of fabricating the semiconductor device further includes forming a backside power distribution network structure on a lower surface of the substrate at the second side of the substrate, wherein the backside contact structure electrically connects the backside power distribution network structure to at least one of the source/drain regions.

In some embodiments, forming the capping patterns includes patterning a stop layer material that is different from a material of the semiconductor structure to define a patterned stop layer having plurality of trenches therein that are spaced apart in the first direction, forming the semiconductor structure on the patterned stop layer, removing the patterned stop layer to expose a patterned surface at the first side of the semiconductor structure, and forming the capping patterns in the patterned surface at the first side of the semiconductor structure.

According to some embodiments, a method of fabricating a semiconductor device includes patterning a stop layer material to define a patterned stop layer having plurality of first trenches therein that are spaced apart in a first direction, forming a semiconductor structure on the patterned stop layer, the semiconductor structure comprising a different material than the patterned stop layer and having a first side thereof facing the patterned stop layer, removing the patterned stop layer to expose a patterned surface having a plurality of second trenches therein on the first side of the semiconductor structure, and forming source/drain regions and channel structures extending therebetween at a second side of the semiconductor structure that is opposite the first side. The channel structures vertically overlap the second trenches in the patterned surface on the first side of the semiconductor structure, respectively.

In some embodiments, opposing side surfaces of the channel structures are substantially aligned with opposing sidewalls of the second trenches in the patterned surface, respectively, in a second direction that is perpendicular to the first direction.

In some embodiments, the method of fabricating the semiconductor device further includes forming capping patterns in the second trenches in the patterned surface at the first side of the semiconductor structure, wherein opposing side surfaces of the capping patterns are substantially aligned with opposing side surfaces of the channel structures, respectively, and forming a backside contact structure that contacts at least one of the source/drain regions and is aligned based on adjacent ones of the capping patterns.

In some embodiments, forming the backside contact structure includes forming a placeholder on at least one of the source/drain regions, wherein the placeholder extends between the adjacent ones of the capping patterns.

In some embodiments, forming the placeholder includes forming an opening at the first side of the semiconductor structure that extends between the adjacent ones of the capping patterns and overlaps the at least one of the source/drain regions in the second direction and forming the placeholder in the opening.

In some embodiments, forming the backside contact structure further includes removing the semiconductor structure and the capping patterns, forming a substrate on the placeholder, the at least one of the source/drain regions, and the channel structures, wherein the channel structures and the at least one of the source/drain regions are at a first side of the substrate, patterning a second side of the substrate that is opposite the first side of the substrate in the second direction to form a first opening therein that exposes the placeholder, and replacing the placeholder with the backside contact structure.

In some embodiments, replacing the placeholder includes removing the placeholder to form a second opening in the substrate that is coupled to the first opening and overlaps the at least one of the source/drain regions in the second direction, and forming the backside contact structure in the first opening and the second opening.

In some embodiments, respective side surfaces of the first opening and the second opening have different slopes. The backside contact structure includes a lower contact structure in the first opening and an upper contact structure in the second opening between the lower contact structure and the at least one of the source/drain regions.

In some embodiments, the respective side surfaces of the first opening and the second opening define a step difference therebetween, and the upper contact structure has a trapezoid shape in a cross-sectional view.

In some embodiments, the method of fabricating the semiconductor device further includes forming a backside power distribution network structure at the second side of the substrate, wherein the backside contact structure electrically connects the backside power distribution network structure to the at least one of the source/drain regions.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1A is a plan or layout view illustrating an integrated circuit device including self- aligned backside contact structures according to some embodiments.

FIGS. 1B and 1C are cross-sectional views taken along line A-A′ of FIG. 1A, illustrating integrated circuit devices including self-aligned backside contact structures according to some embodiments.

FIGS. 2A, 2B, 2C, 2D, 2E, and 2F are cross-sectional views illustrating a method of forming a patterned stop layer for fabricating self-aligned backside contact structures according to some embodiments.

FIGS. 3A, 3B, 3C, 3D, and 3E are cross-sectional views illustrating a method of forming capping patterns based on the patterned stop layer for fabricating self-aligned backside contact structures according to some embodiments.

FIGS. 4A, 4B, 4C, 4D, 4E, and 4F are cross-sectional views illustrating a method of forming placeholder elements that are self-aligned based on the capping patterns for fabricating self-aligned backside contact structures according to some embodiments.

FIGS. 5A, 5B, 5C, 5D, 5E, 5F, and 5G are cross-sectional views illustrating a method of forming self-aligned backside contact structures using the placeholder elements according to some embodiments.

FIGS. 6A, 6B, and 6C are cross-sectional views illustrating a method of forming self- aligned backside contact structures using the placeholder elements according to some embodiments.

FIG. 7 is a flowchart illustrating a method of forming a patterned stop layer according to some embodiments.

FIG. 8 is a flowchart illustrating a method of forming capping patterns based on the patterned stop layer according to some embodiments.

FIG. 9 is a flowchart illustrating a method of forming placeholder elements that are self- aligned based on the capping patterns according to some embodiments.

FIG. 10 is a flowchart illustrating a method of forming self-aligned backside contact structures using the placeholder elements according to some embodiments.

### DETAILED DESCRIPTION OF EMBODIMENTS

A BSPDN structure may include a power delivery network that includes one or more power rails on (in) a backside of a semiconductor device. Different ways to connect from the frontside to the backside may include, for example, a front via backside power rail (FV-BPR) and a direct backside contact (DBC). The DBC may be more effective in terms of process capability and dimension limitations than other ways of connecting the frontside to the backside. As contacted poly pitch (CPP) becomes smaller, however, DBCs may be more difficult to form due to patterning issues such as photo overlay and high aspect ratio etch process (which may result in voids in the DBCs and shorts between the DBCs).

In a DBC scheme, due to the wafer warpage and distortion, connection to a source/drain region (S/D region) or a gate structure may be challenging in terms of lithography overlay. Forming a frontside contact structure may be less difficult because the frontside contact structure may be above a channel structure, a gate structure, and a source/drain region. However, in case of backside contact, a contact etch process may be performed from the backside of the semiconductor structure (e.g., between the nanosheet channels, which are on the frontside), and thus, the fabrication process may be more challenging.

Pursuant to embodiments herein, semiconductor (e.g., integrated circuit) devices are provided with self-aligned backside contact structures. In particular embodiments, a self-aligned backside contact structure may be formed using a different-or varying-height (e.g., uneven) silicon germanium (SiGe) stop layer that is patterned based on locations of the channel structures on an opposite side of the semiconductor structure, corresponding capping patterns (e.g., silicon nitride (SiN) nanosheet capping patterns) that are aligned with the channel patterns based on the patterned stop layer, and a backside placeholder element that is self-aligned based on the capping patterns. Some examples of embodiments of the present disclosure are described in greater detail with reference to the attached figures.

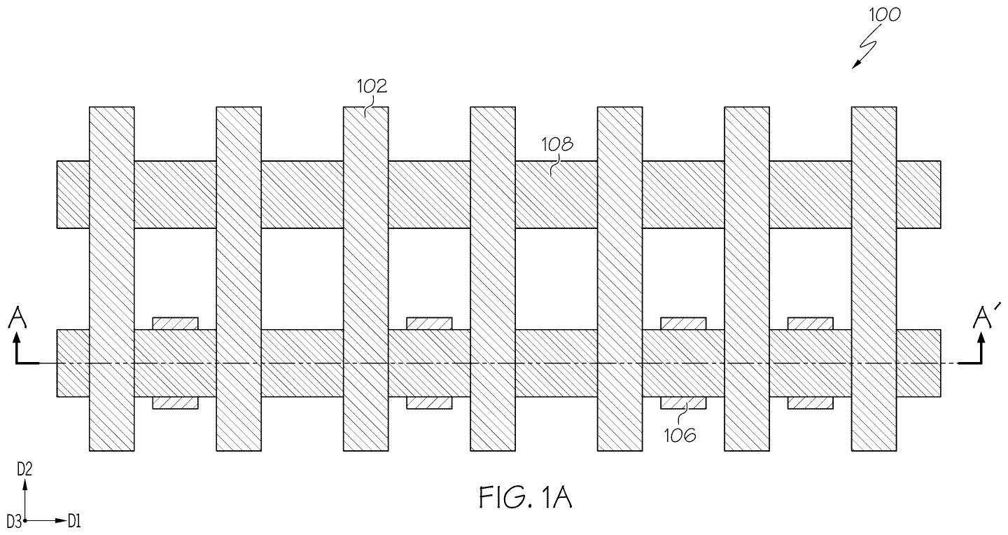

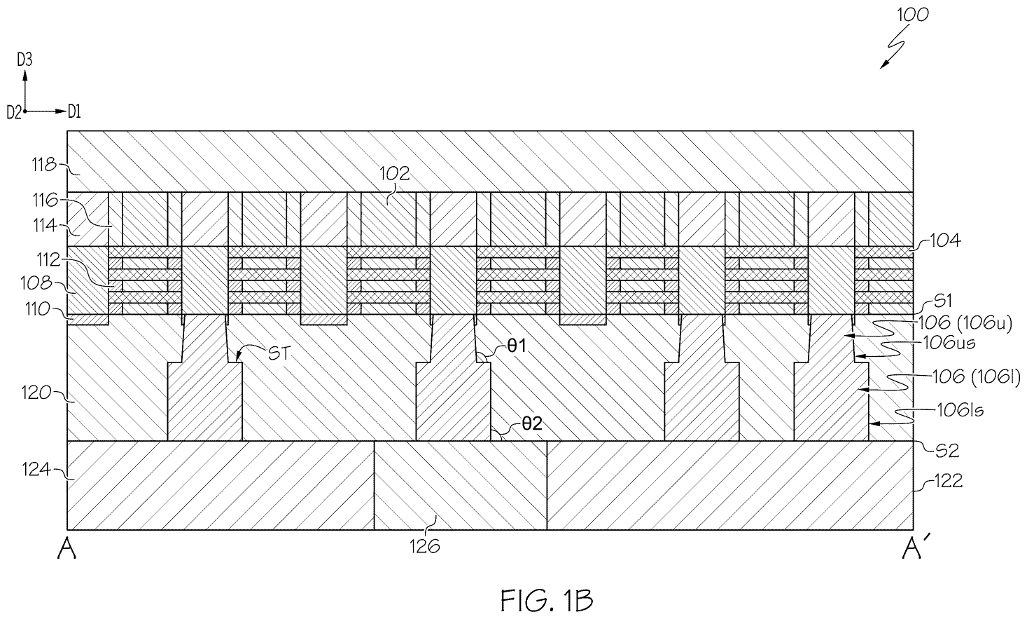

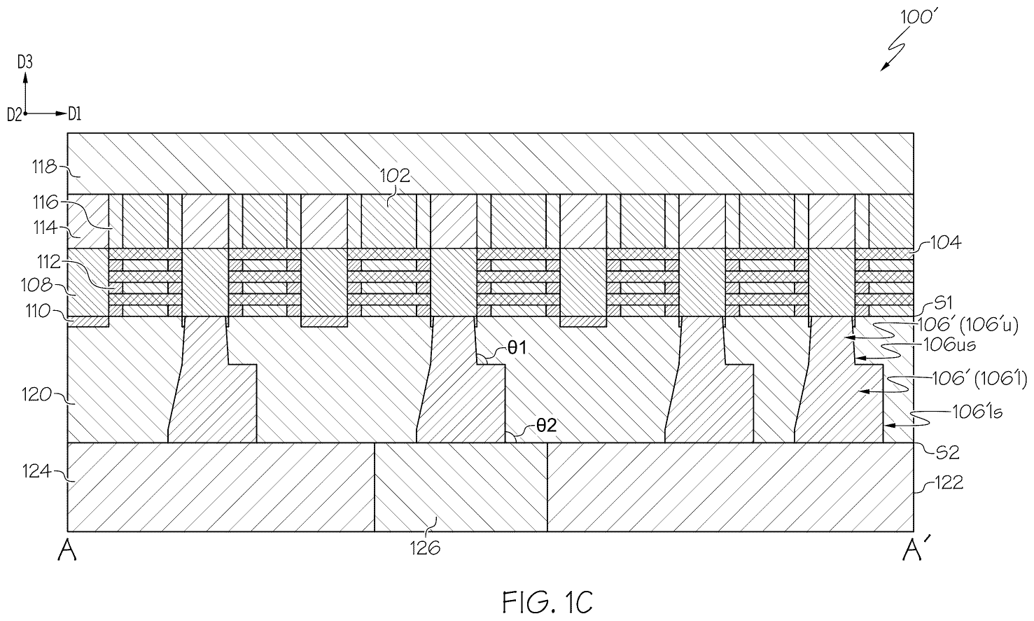

FIG. 1A is a plan or layout view illustrating an integrated circuit device 100 including self-aligned backside contact structures according to some embodiments. FIGS. 1B and 1C are cross-sectional views taken along line A-A′ of FIG. 1A, illustrating an integrated circuit device including self-aligned backside contact structures according to some embodiments.

Referring to FIGS. 1A and 1B, the integrated circuit device 100 may include a substrate 120 (also referred to as a backside insulating layer) and transistor structures TS (also referred to as transistors) on a first side (or frontside) S1 of the substrate 120. The substrate 120 may extend in a first direction D1 (also referred to as a first horizontal direction or X direction) and a second direction D2 (also referred to as a second horizontal direction or Y direction). The first direction D1 and the second direction D2 may be parallel to a surface (e.g., the frontside S1) of the substrate 120. In some embodiments, the first direction D1 may be perpendicular to the second direction D2.

In some embodiments, the substrate 120 may include or may be formed of insulating material(s), for example, silicon oxide, silicon oxynitride, silicon nitride, silicon carbonitride, silicon boron nitride and/or a low-k dielectric material. The low-k dielectric material may include, for example, fluorine-doped silicon oxide, organosilicate glass, carbon-doped oxide, porous silicon dioxide, porous organosilicate glass, spin-on organic polymeric dielectrics and/or spin-on silicon based polymeric dielectric. In some embodiments, the substrate 120 may include or may be semiconductor material(s), for example, Si, Ge, SiGe, GaP, GaAs, SiC, SiGeC and/or InP. For example, the substrate 120 may be insulating layer(s), a bulk substrate (e.g., a bulk silicon wafer) and/or a semiconductor-on-insulator (SOI) substrate. A thickness of the substrate 120 in a third direction D3 (also referred to as a vertical direction or Z direction) may be, for example, in a range of (about) 50 nm to 100 nm. In some embodiments, the third direction D3 may be perpendicular to the first direction D1 and/or the second direction D2. The third direction D3 may be perpendicular to the surface (e.g., the frontside S1) of the substrate 120.

Each of the transistor structures TS may include a gate structure 102 and a channel structure 104 that extends between source/drain regions 108 (in the first direction D1). The gate structure 102 may overlap the channel structure 104 in the third direction D3. In some embodiments, the channel structure 104 may extend in the first direction D1, and the gate structure 102 may extend in the second direction D2. In some embodiments, each of the transistor structures TS may include multiple channel structures 104 stacked in the third direction D3, and the channel structures 104 may be spaced apart from each other in the third direction D3. For example, the transistor structures TS may be nanosheet transistors that include a stack of nanosheet layers in each channel structures 104. A gate insulator (not illustrated) may extend between the gate structures 102 and the channel structures 104. More particularly, the gate insulator may contact and physically separate the gate structure 102 and the channel structure 104 (including nanosheets thereof).

Each of the transistor structures TS may also include a pair of source/drain regions 108 that are spaced apart from each other in the first direction D1. The gate structure 102 may be provided between the pair of source/drain regions 108. The source/drain regions 108 may contact opposing side surfaces of the channel structure 104 that are spaced apart from each other in the first direction D1. The transistor structure TS may further include a lower gate insulating spacer 112 between the gate structure 102 and the source/drain region 108 (in the first direction D1).

The channel structure 104 may include semiconductor material(s) (e.g., Si, Ge, SiGe, GaP, GaAs, SiC, SiGeC and/or InP). In some embodiments, the channel structures 104 may include nanosheets that may have a thickness, for example, in a range from (about) 1 nanometer (nm) to 100 nm in the third direction D3 or may be a nanowire that may have a circular cross- section with a diameter, for example, in a range of from (about) 1 nm to 100 nm. When the channel structure 104 includes a nanosheet or nanowire, the gate structure 102 may extend around (at least partially surround) the channel structure 104 on multiple sides.

Each of the source/drain regions 108 may include a semiconductor layer (e.g., a silicon (Si) layer and/or a silicon germanium (SiGe) layer) and may additionally include dopants in the semiconductor layer. In some embodiments, an etch stop layer 110 may be disposed on a lower surface (e.g., a bottom surface) of each of the source/drain regions 108. The etch stop layer 110 may include a material that has an etch selectivity with respect to the source/drain region 108. In some embodiments, the etch stop layer 110 may include a SiGe layer. In some embodiments, the etch stop layer 110 may be a part of the source/drain region 108. For example, the etch stop layer 110 may be a lower portion of the respective source/drain region 108. The lower portion of the source/drain region 108 (e.g., the etch stop layer 110) may have an etch selectivity to an upper portion of the source/drain region 108 on the lower portion of the source/drain region 108. For example, the lower portion of the source/drain region 108 (e.g., the etch stop layer 110) and the upper portion of the source/drain region 108 may have different Ge proportions (e.g., different Ge concentrations). The gate insulator (not illustrated) may include a single layer or multiple layers (e.g., a silicon oxide layer and/or a high-k dielectric material layer). For example, the high-k dielectric material layer may include Al₂O₃, HfO₂, ZrO₂, HfZrO₄, TiO₂, Sc₂O₃, Y₂O₃, La₂O₃, Lu₂O₃, Nb₂O₅ and/or Ta₂O₅.

The integrated circuit device 100 may include multiple gate structures 102 that extend (i.e., longitudinally) in the second direction D2 and are spaced apart from each other in the first direction D1. Each of the gate structures 102 may include a single layer or multiple layers. In some embodiments, each of the gate structures 102 may include a metal layer or material that includes, for example, tungsten (W), aluminum (Al), copper (Cu), molybdenum (Mo), cobalt (Co) and/or ruthenium (Ru), and may additionally include work function layer(s) (e.g., a TiN layer, a TaN layer, a TiAl layer, a TiC layer, a TiAIC layer, a TiAIN layer and/or a WN layer). In some embodiments, each of the gate structures 102 may include the same material(s).

In some embodiments, the transistor structure TS may be a three-dimensional (3D) field effect transistor (FET) such as a multi-bridge channel FET (MBCFET). In some embodiments, the transistor structure TS may have a structure different from that illustrated. For example, the transistor structure TS may be a gate-all-around FET (GAAFET) including a single channel structure or a fin-shaped FET (FinFET).

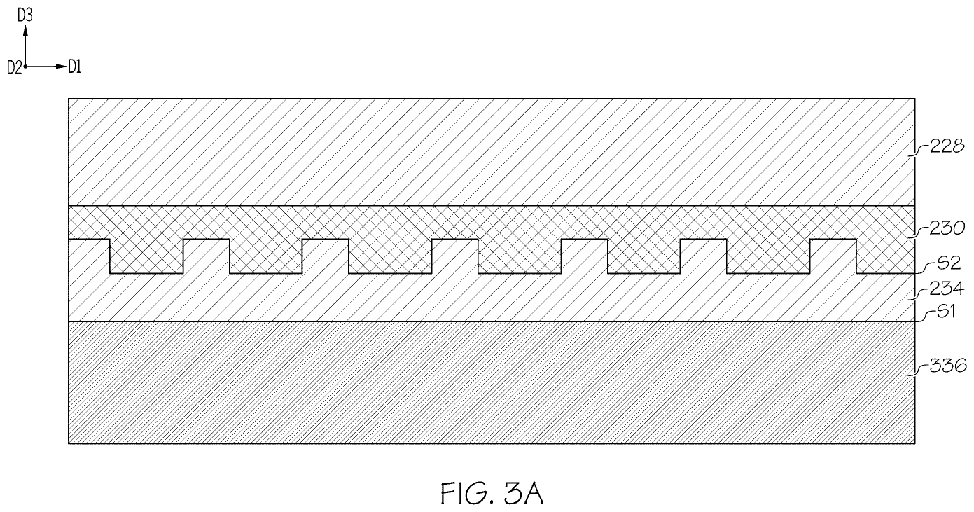

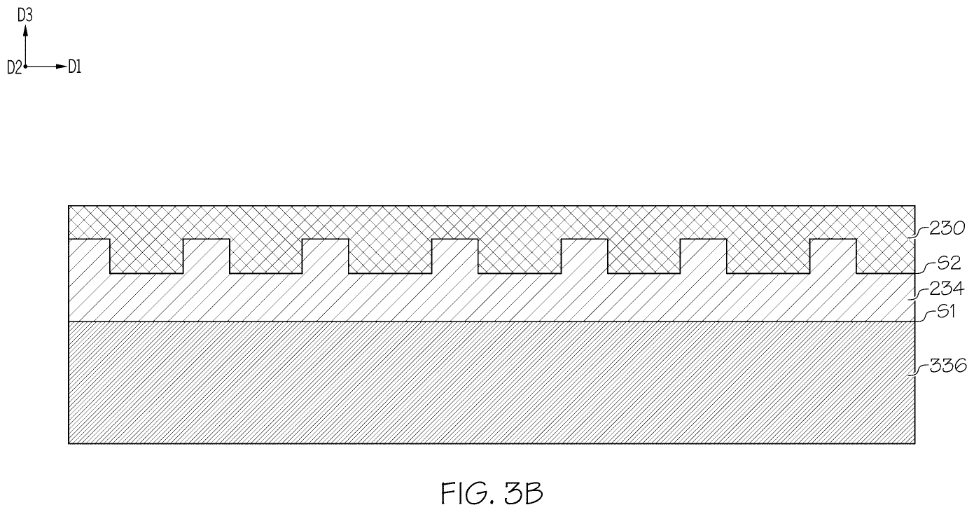

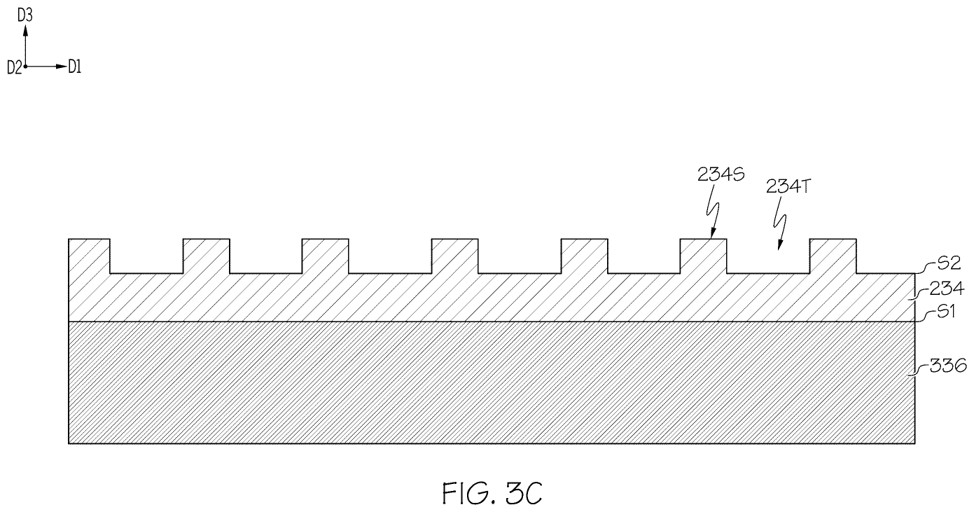

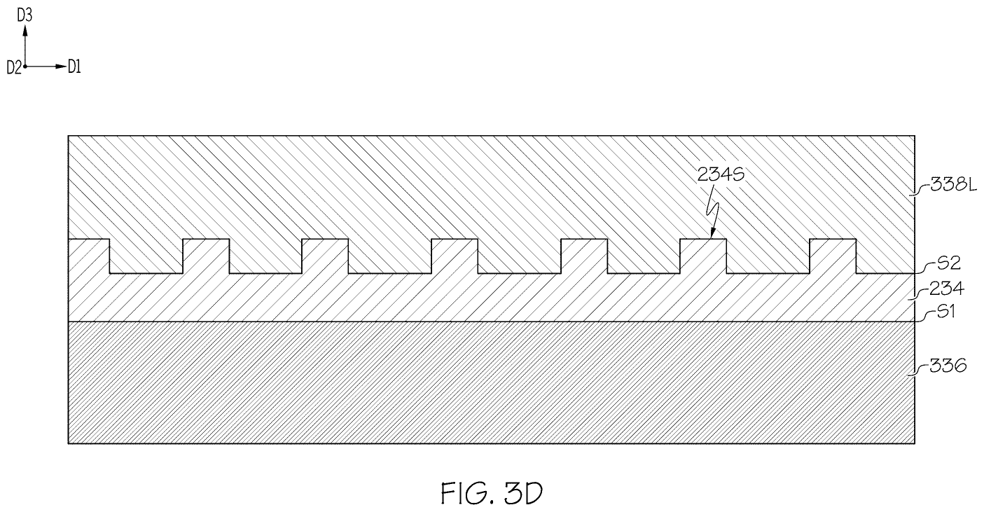

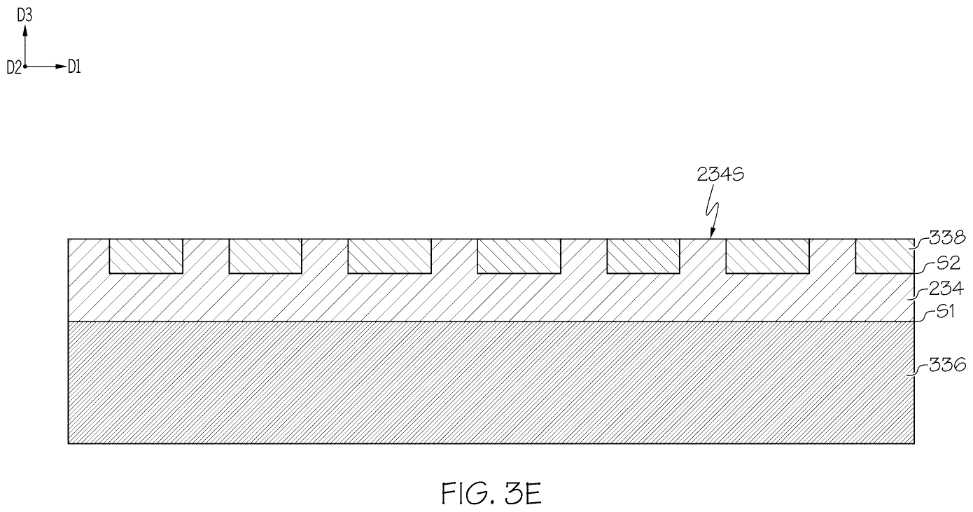

As shown in greater detail in the cross-sectional view of FIG. 1B, the channel structures 104, the gate structure 102, and the source/drain regions 108 may be provided on the frontside S1 of the substrate 120. The integrated circuit device 100 may further include backside contact structures 106 that are electrically connected to the source/drain regions 108. The backside contact structures 106 may extend through the substrate 120 from the backside S2 of the substrate 120 to contact the source/drain regions 108 on the frontside S1 of the substrate 120. The upper portions 106u of the backside contact structures 106 may not overlap the channel structures 104 in the third direction D3, and may be formed in a self-aligned manner based on capping patterns (e.g., capping patterns 338 to be described later in FIG. 3E) that are aligned with the channel structures 104 on the opposite side (in the third direction D3) of semiconductor structure 234, as described in greater detail below.

The backside contact structures 106 (also referred to herein as backside source/drain contacts 106) may respectively contact lower portions (e.g., bottom portions) or lower surfaces (e.g., bottom surfaces) of the source/drain regions 108. The backside source/drain contacts 106 and/or the backside gate contact structure (not illustrated) may include a metal layer or material including, for example, W, Al, Cu, Mo, Co and/or Ru. The etch stop layers 110 may be between the lower surfaces of the source/drain regions 108 and the substrate 120 (in the third direction D3). The backside source/drain contacts 106 may extend through (in the third direction D3) the etch stop layers 110 to contact (lower portions or lower surfaces of) the source/drain regions 108. Some of the etch stop layers 110 and the source/drain regions 108 thereon may not overlap the backside source/drain contacts 106 in the third direction D3. For example, some of the source/drain regions 108 may not be in contact with the backside source/drain contacts 106.

The integrated circuit device 100 may further include an isolation pattern 114 on the frontside S1 of the substrate 120 between (a pair of) channel structures 104 that are adjacent each other (in the first direction D1). The integrated circuit device 100 may further include a lower gate insulating spacer 112 between the gate structure 102 and the source/drain region 108 (in the first direction D1) and an upper gate insulating spacer 116 between the gate structure 102 and the isolation pattern 114 (in the first direction D1). In some embodiments, the lower gate insulating spacer 112 and the upper gate insulating spacer 116 may include the same material and may be formed by the same process or the same series of processes. In some embodiments, the lower gate insulating spacer 112 and the upper gate insulating spacer 116 may be omitted. Each of the lower gate insulating spacer 112, the isolation pattern 114, and the upper gate insulating spacer 116 may include, for example, silicon oxide, silicon oxynitride, silicon nitride, silicon carbonitride and/or a low-k material.

Still referring to FIG. 1B, the backside contact structure 106 may include a lower contact structure 1061 and an upper contact structure 106u on the lower contact structure 106l. In some embodiments, the upper contact structure 106u may not overlap the channel structure 104 in the third direction D3, and the lower contact structure 106l may overlap the channel structure 104 in the third direction D3. The upper contact structure 106u may contact (e.g., may be directly on) the source/drain region 108 and may extend between the lower contact structure 106l and the source/drain region 108. The upper contact structure 106u and the lower contact structure 106l may be a monolithic or unitary structure that is formed from a same material (i.e., without structurally or visibly separate interfaces therebetween) in some embodiments. Respective side surfaces 106us, 106ls of the upper and lower contact structures 106u, 106l may be formed at different angles θ1, θ2, and thus, have different slopes. For example, a first slope of the side surface 106us (e.g., having a first angle 01) of the upper contact structure 106u may be less than a second slope of the side surface 106ls (e.g., having a second angle 02) of the lower contact structure 106l, or vice versa. Also, the respective side surfaces 106us, 106ls of the upper and lower contact structures 106u, 106l may not be aligned, resulting in at least one step difference ST between the respective side surfaces 106us, 106ls of the upper and lower contact structures 106u, 106l. In some embodiments, the backside contact structure 106 may have a symmetric shape (in the first direction D1).

FIG. 1C is a cross-sectional view taken along line A-A′ of FIG. 1A, illustrating an integrated circuit device 100′ including self-aligned backside contact structures 106′ according to some embodiments. As shown in FIG. 1C, the backside contact structure 106′ (corresponding to the backside contact structure 106 in FIG. 1B) may have an asymmetric shape (in the first direction D1), with a more significant misalignment (and thus, a more pronounced step difference ST) between the respective side surfaces 106′us, 106′ls (corresponding to the respective side surfaces 106us, 106ls in FIG. 1B) of the upper and lower contact structures 106′u, 106′l (corresponding to the upper and lower contact structures 106u, 106l in FIG. 1B). The embodiment of FIG. 1C is otherwise similar to that of FIG. 1B, and repeated description of similar elements may be omitted for brevity.

Still referring to FIGS. 1B and 1C, the upper contact structure 106u may have a greater (e.g., greatest) width (in the first direction D1) adjacent the lower contact structure 106l and a lesser (e.g., least) width (in the first direction D1) adjacent the source/drain region 108. In some embodiments, the width of the upper contact structure 106u in the first direction may continuously (e.g., uniformly) decrease as the upper contact structure 106u approaches from the lower contact structure 106l to the source/drain region 108. For example, the upper contact structure 106u may have a trapezoid shape in a cross-sectional view.

As shown in FIGS. 1B and 1C, a backside power distribution network (BSPDN) structure 122 may be provided on the second side or backside S2 of the substrate 120, and the backside contact structure 106 (106′) may electrically connect the BSPDN structure 122 to the source/drain region 108. The BSPDN structure 122 may be provided on a lower surface of the backside contact structure 106 (106′) and a lower surface of the substrate 120. The BSPDN structure 122 may include a backside insulator 124 and one or more backside power rails 126 provided in the backside insulator 124. The backside power rail 126 may be electrically connected to lower contact structure 106l (106′l) of the backside contact structure 106 (106′). The backside power rail 126 may include a metal layer or material including, for example, W, Al, Cu, Mo, Co and/or Ru.

The backside power rail 126 may be electrically connected to a power source with a predetermined voltage (e.g., a drain voltage or a source voltage). For example, the BSPDN structure 122 may include a power delivery network. The power delivery network may include a wiring network, which is used to deliver power (e.g., gate voltages and/or source/drain voltages) to the backside power rail 126. The source/drain regions 108 may be electrically connected to the power source through the backside contact structure 106 and the backside power rail 126. The backside contact structure 106 may be between the backside power rail 126 and the source/drain regions 108 in the third direction D3. In some embodiments, one or more conductive plugs may be provided between the backside contact structure 106 and the backside power rail 126. The backside contact structure 106 and the conductive plug may include the same materials. For example, the backside contact structure 106 and the conductive plug may be integrated in a monolithic or unitary structure, that is, a structure formed by the same process or the same series of processes without a structurally or visibly separate interfaces therebetween.

As used herein, the backside power rail 126 may refer to one or more conductive elements included in the BSPDN structure 122. For example, the backside power rail 126 may include a power rail, a conductive via plug, and/or a conductive wire included in the BSPDN structure 122. That is, while illustrated as including the backside power rail 126 and the backside insulator 124, it will be understood that the BSPDN structure 122 may include one or more conductive layers (e.g., metal layers) stacked in the third direction D3 that provide backside power delivery to the transistor structure TS. The conductive layers may be respectively included in insulating layers, and conductive via plugs (e.g., metal via plugs) may electrically connect the conductive layers to each other in the third direction D3. For example, although the backside insulator 124 is illustrated as a single layer, in some embodiments, the backside insulator 124 may include multiple layers stacked on the backside S2 (e.g., a lower surface) of the substrate 120. The conductive layers may include one or more conductive wires (e.g., metal wires). In some embodiments, an intervening structure may be provided between the substrate 120 and the BSPDN structure 122 and may separate the substrate 120 from the BSPDN structure 122. The BSPDN structure 122 may increase a power delivery efficiency in the integrated circuit device 100, reduce an area used for power delivery in the integrated circuit device 100, and/or improve a voltage drop (i.e., IR drop) in the integrated circuit device 100.

As shown in FIGS. 1B and 1C, the integrated circuit device 100 may further include an upper structure 118 on the gate structures 102 and the isolation patterns 114. The upper structure 118 may include elements formed by the middle-of-line (MOL) portion and/or the back-end-of-line (BEOL) portion of device fabrication. The upper structure 118 may include conductive elements (e.g., a wire or a via plug) and insulating elements (e.g., an interlayer or a spacer). The conductive elements of the upper structure 118 may be electrically connected to, for example, the source/drain region 108 and/or the gate structure 102.

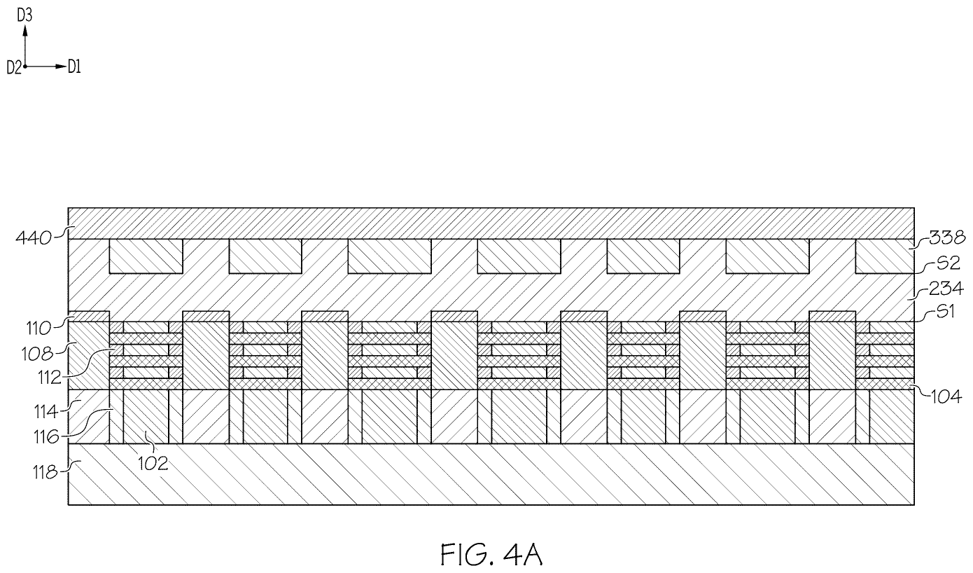

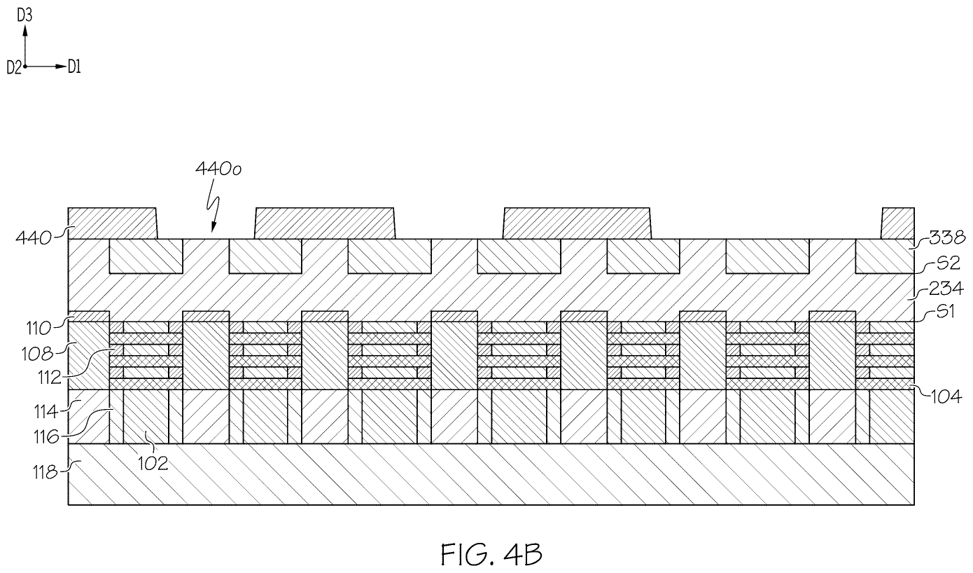

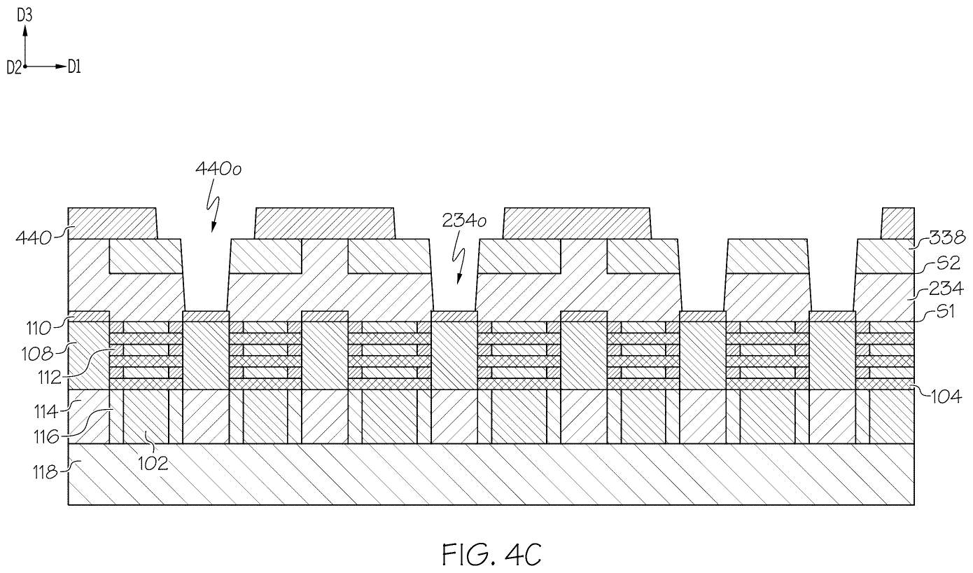

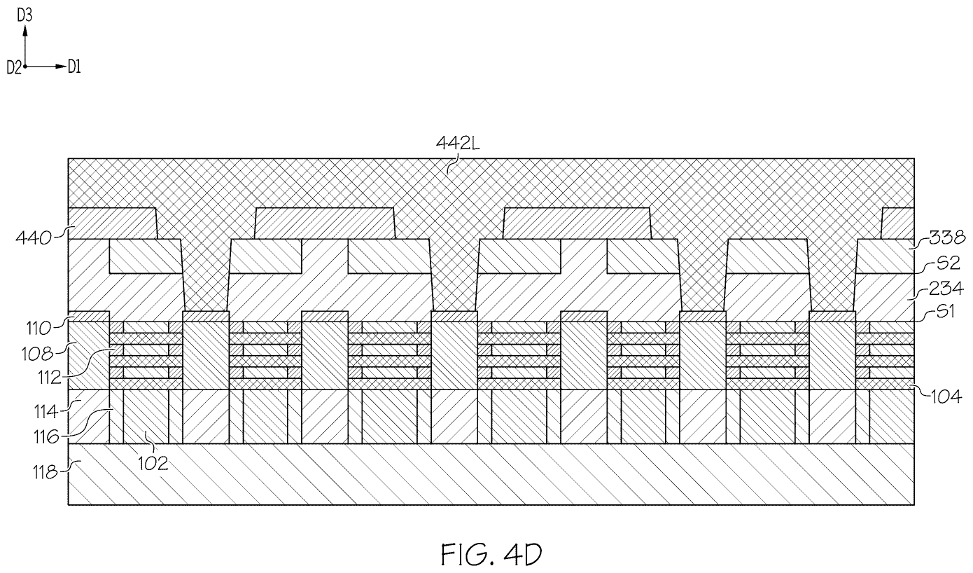

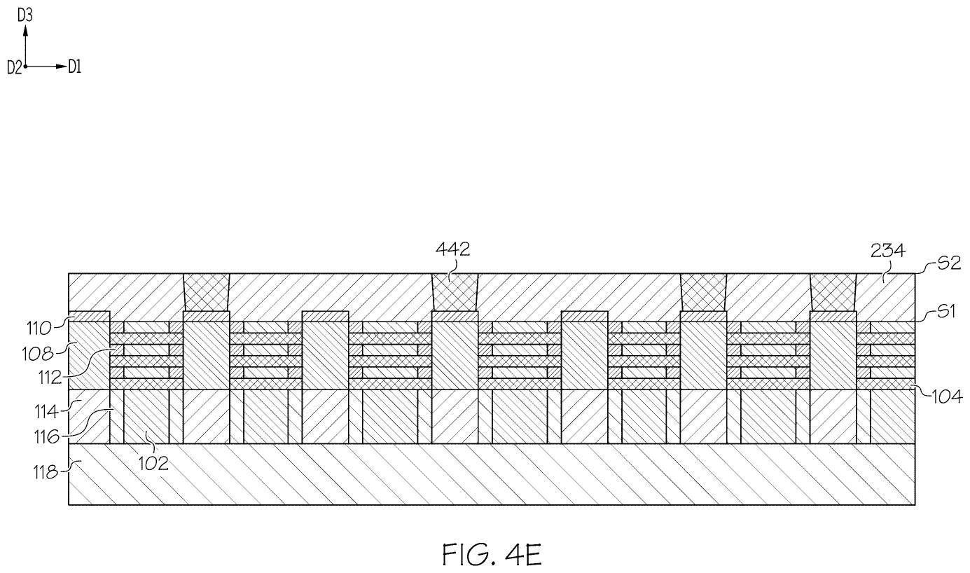

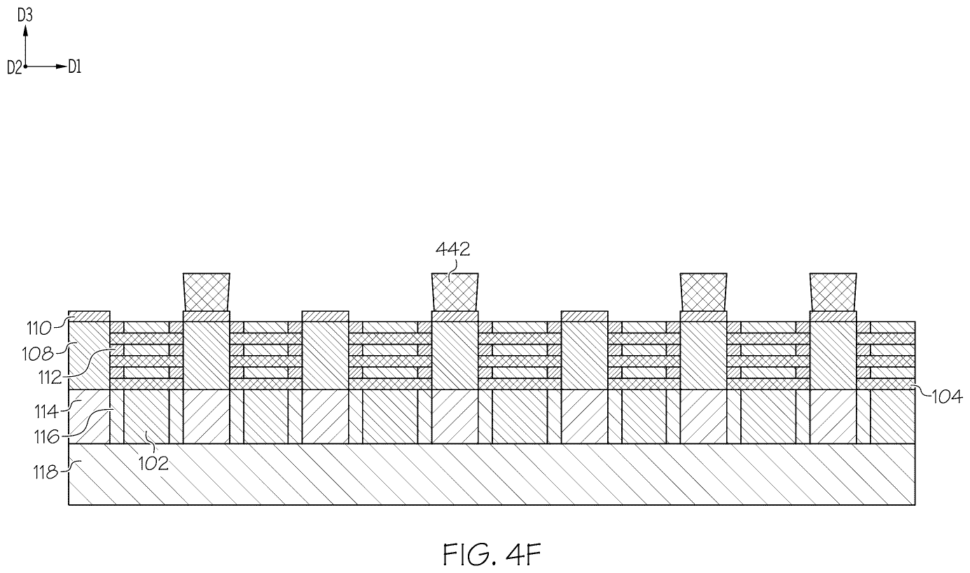

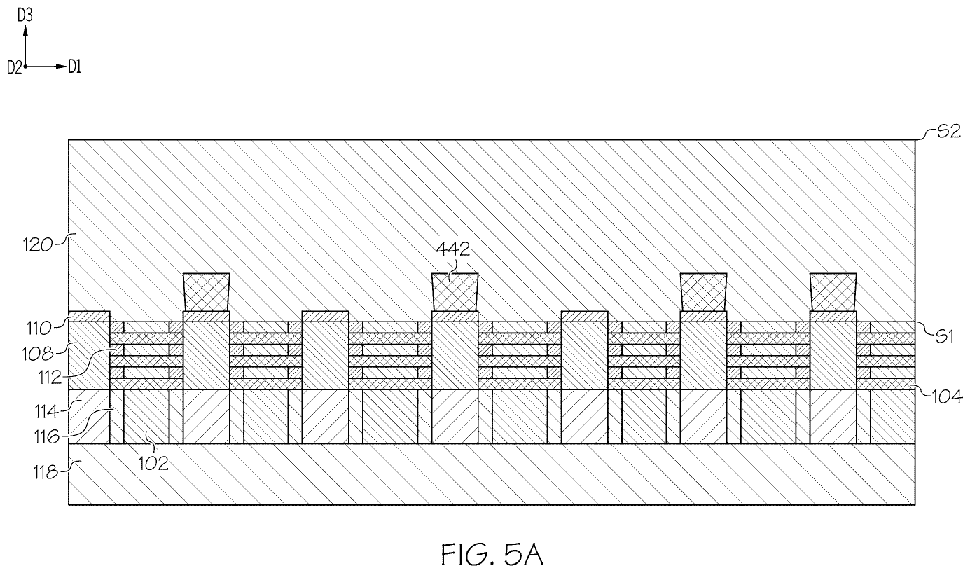

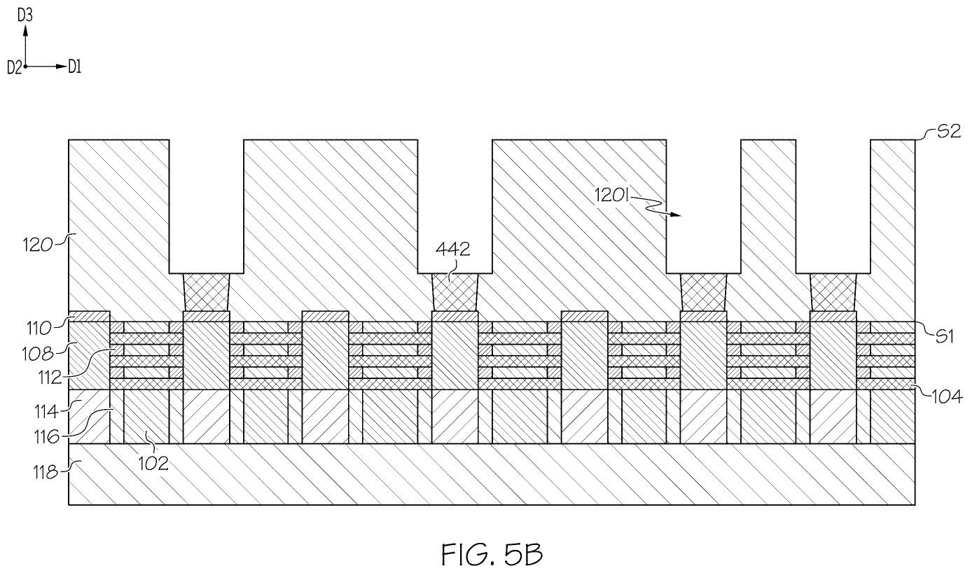

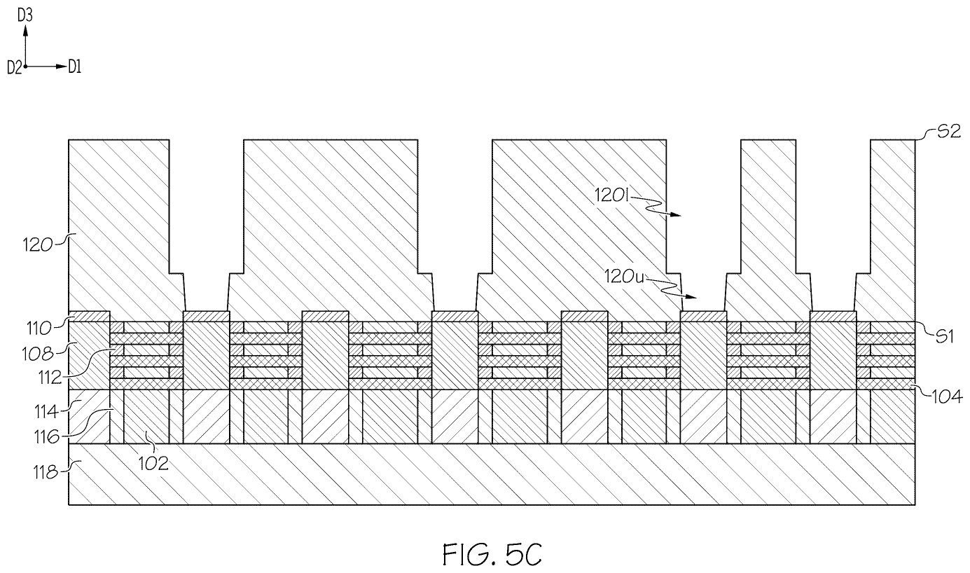

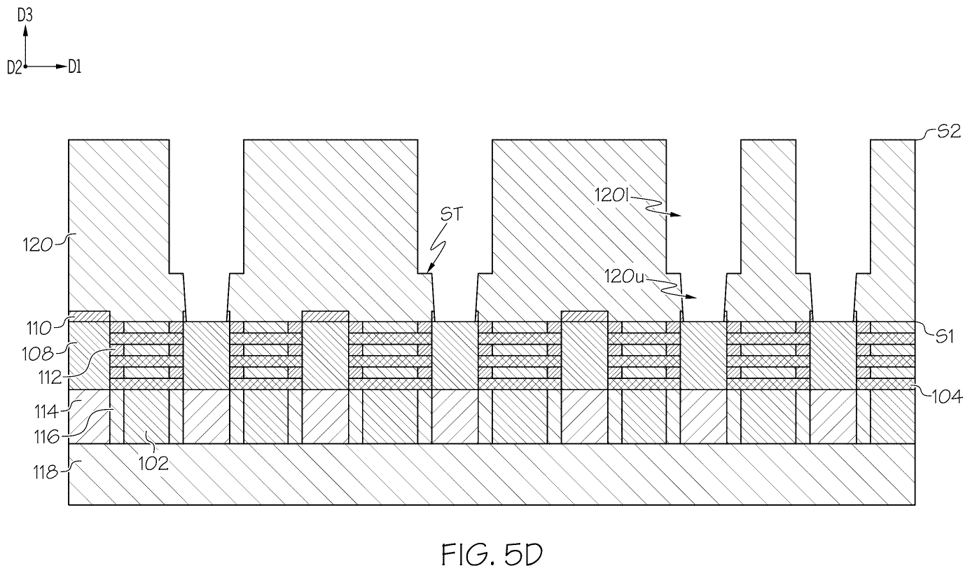

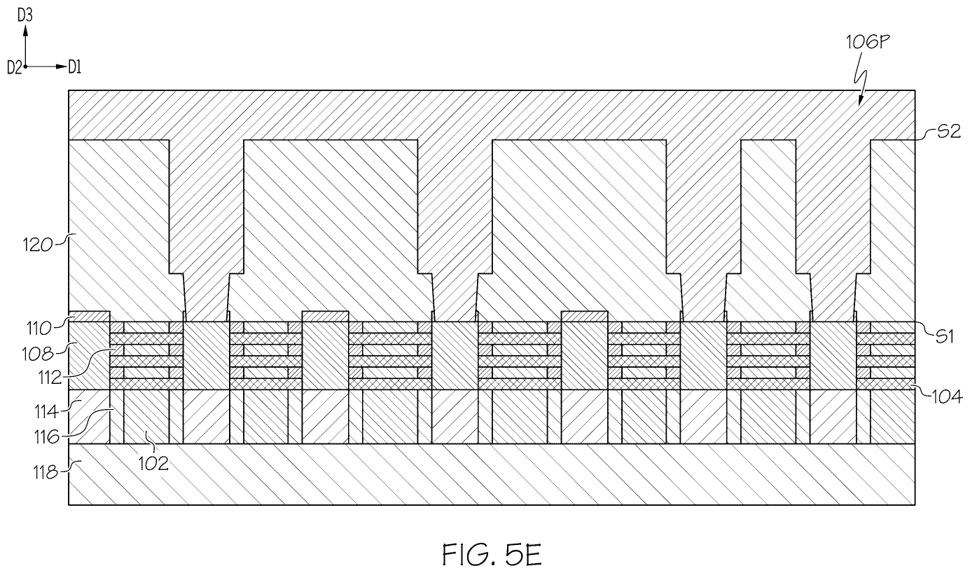

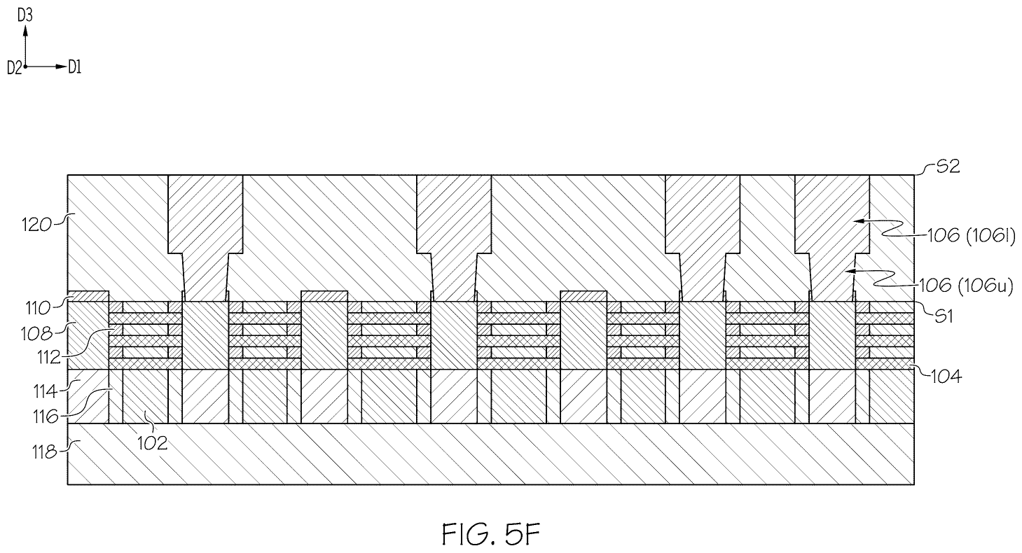

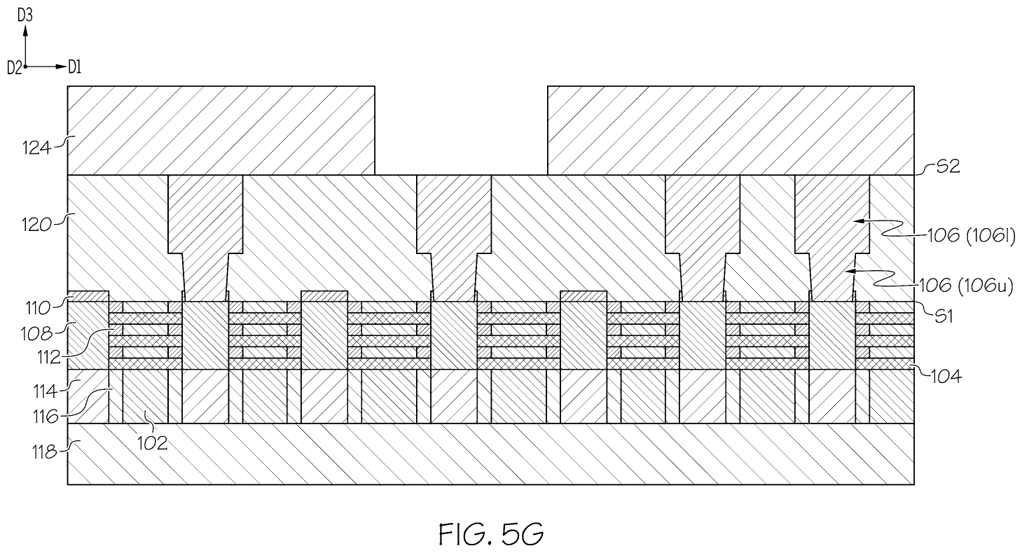

As described in greater detail below, the integrated circuit device 100 may further include source/drain placeholder elements (also referred to herein as placeholders) 442 (which will be described later referring to FIGS. 4F and 5A) that are formed in the substrate 120 (e.g., in the upper portion of the substrate 120). The placeholders 442 may be replaced with the upper contact structure 106u in the subsequent processes. The placeholder 442 may include a material different from the backside contact structure 106 and/or the substrate 120. The placeholder 442 may include, for example, a semiconductor material (e.g., Si or SiGe) and/or an insulating material (e.g., silicon oxide, silicon oxynitride, silicon nitride, silicon carbonitride, silicon boron nitride and/or a low-k material). In a process of replacing a silicon substrate or other semiconductor structure 234 (described later in detail) with the substrate 120, the placeholder 442 may be formed, and the backside contact structure 106 may be formed by replacing the placeholder 442 via a self-aligned form in a unique shape as shown in FIGS. 1B and 1C.

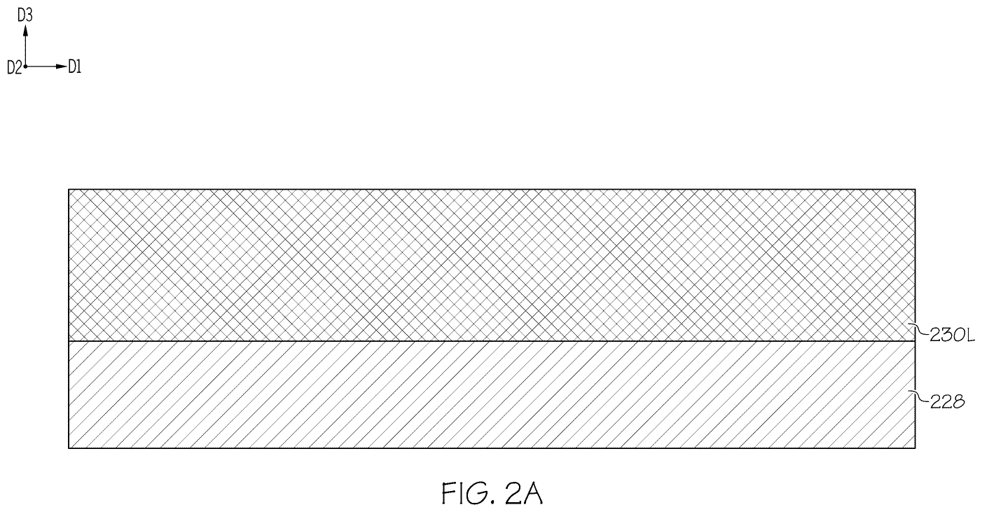

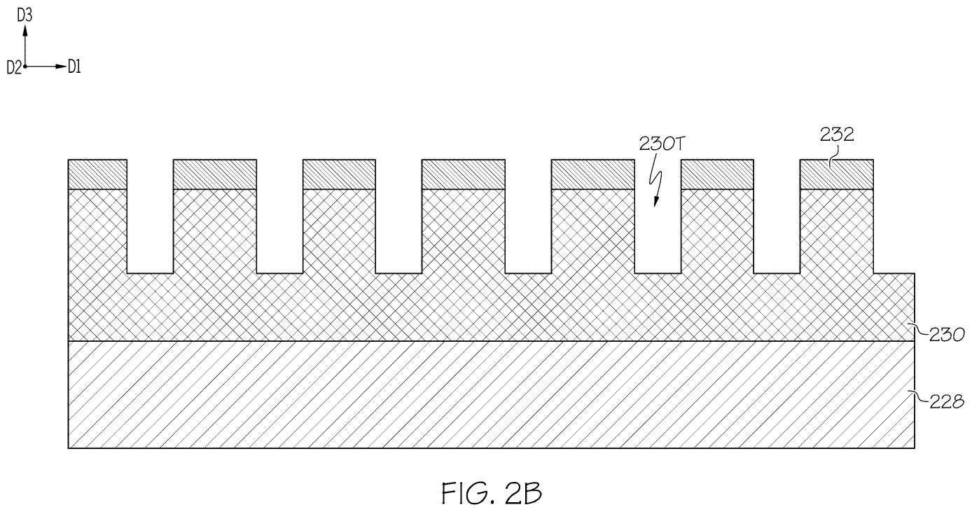

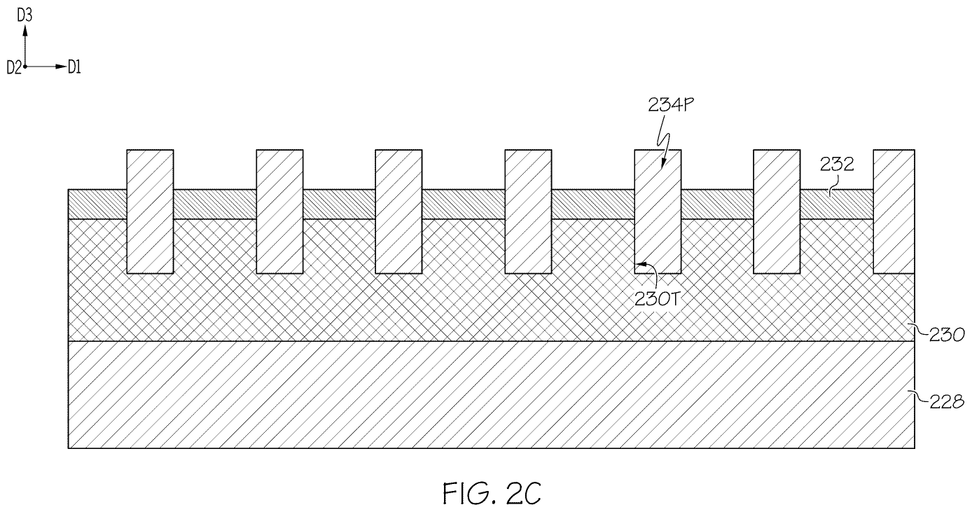

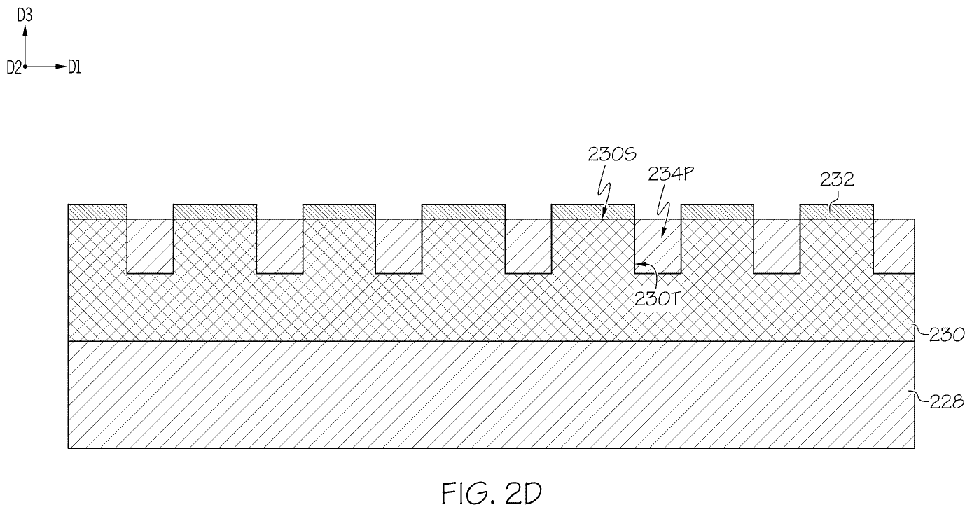

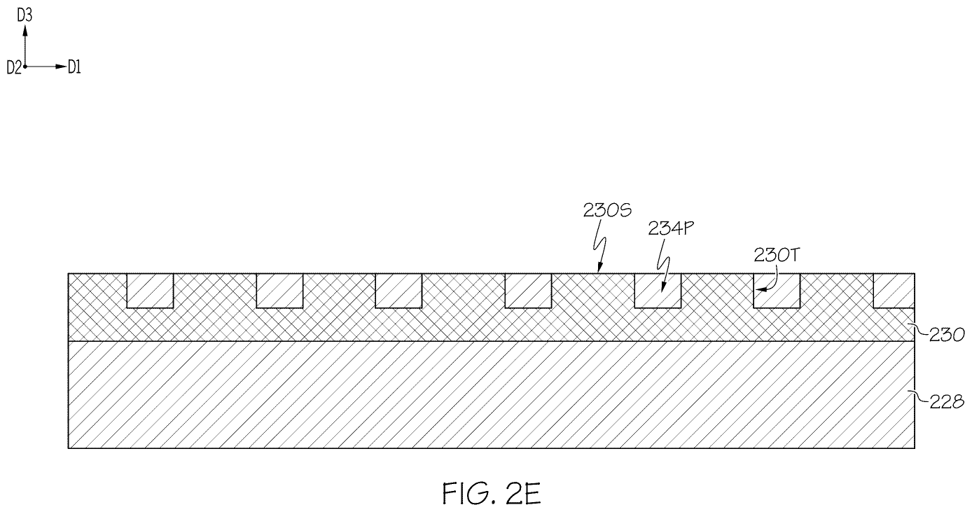

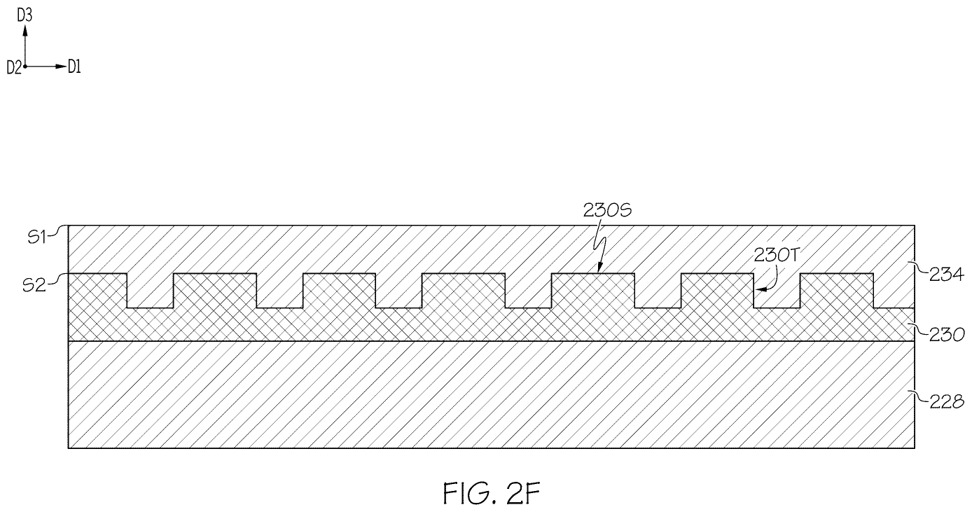

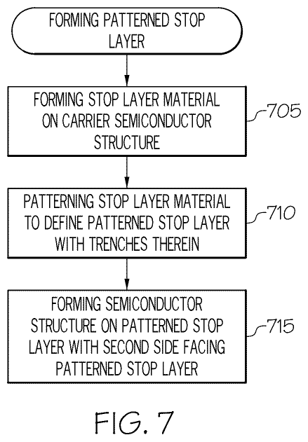

FIGS. 2A, 2B, 2C, 2D, 2E, and 2F are cross-sectional views and FIG. 7 is a flowchart illustrating a method of forming a patterned stop layer 230 for fabricating self-aligned backside contact structures 106 according to some embodiments. As shown in FIG. 2A, a stop layer material 230L may be formed on a carrier semiconductor structure 228 (at block 705 in FIG. 7). The stop layer material 230L and the carrier semiconductor structure 228 may include (e.g., may be formed of) different materials, e.g., semiconductor materials having etch selectivity to one another for selective etching processes as described herein. For example, the carrier semiconductor structure 228 may include silicon (Si), while the stop layer material 230L may include silicon germanium (SiGe).

As shown in FIG. 2B, a stop layer mask pattern 232 (for example, an oxide mask pattern) may be formed on the stop layer material 230L, and the stop layer material 230L may be patterned to form a patterned stop layer 230 having plurality of trenches 230T therein on the carrier semiconductor structure 228 (at block 710 in FIG. 7). The patterned stop layer 230 may provide a backside thinning stop layer for the operations shown in FIG. 3B. The stop layer mask pattern 232 used to form the patterned stop layer 230 may include a corresponding or complementary pattern as a channel mask pattern that is subsequently used to form channel structures 104 as described herein. For example, the stop layer mask pattern 232 and the channel mask pattern may include inverse patterns. That is, the stop layer mask pattern 232 and the channel mask pattern (described below) may be based on complementary patterns, such that the patterning locations for the trenches (or recesses) 230T in the patterned stop layer 230 may correspond to (with respect to the first direction D1) the patterning locations for the channel structures 104. For example, surfaces between each of the trenches 230T may overlap (align) with the respective channel structures 104 in the third direction D3. In some embodiments, the locations of the stop layer mask patterns 232 are disposed may correspond (e.g., overlap in the third direction D3) the gate structures 102 and channel structures 104, respectively.

As shown in FIG. 2C, the semiconductor material may be formed in the trenches 230T in the patterned stop layer 230 (e.g., by epitaxial growth), and a planarization process (e.g., chemical mechanical polishing (CMP) process) may be performed as shown in FIG. 2D such that surfaces 230S of the patterned stop layer 230 and the epitaxially grown semiconductor material are (substantially) coplanar. For example, a chemical mechanical polishing process may be performed such that that silicon germanium patterned stop layer 230 and the epitaxially grown silicon have (substantially) planar surfaces. As shown in FIG. 2E, remaining portions of the stop layer mask pattern 232 may be removed, e.g., using a planarization or cleaning process. For example, remaining oxide materials of an oxide mask pattern (the stop layer mask pattern 232) may be removed by a wet cleaning process. Referring to FIG. 2E, an upper surface of the semiconductor material and an upper surface of the patterned stop layer 230 may be (substantially) coplanar.

As shown in FIG. 2F, the semiconductor material may be epitaxially grown to form a semiconductor structure 234 with a second side (or a backside) S2 on the patterned stop layer 230 (at block 715 in FIG. 7).

In particular embodiments, a SiGe patterned stop layer 230 may be formed using an oxide mask pattern (the stop layer mask pattern 232) in FIG. 2B, including patterns (trenches (or other recesses) 230T) corresponding to that of the channel mask pattern (e.g., a nanosheet mask pattern) that is used to form the channel structures 104 in a subsequent process. After Si epitaxial growth in the patterns of the patterned stop layer 230 in FIG. 2C, a CMP process may be performed in FIG. 2D such that surfaces of the SiGe patterned stop layer 230 and the Si epitaxial layers formed in the trenches 230T therein are (substantially) coplanar. The remaining portions of the oxide mask pattern (the stop layer mask pattern 232) may be removed by a wet cleaning process and/or further planarization in FIG. 2E, and Si may be again epitaxially grown to form the semiconductor structure 234 in FIG. 2F.

That is, a method of fabricating the integrated circuit device 100 may include patterning a stop layer material 230L to define a patterned stop layer 230 having plurality of trenches 230T therein that are spaced apart in the first direction D1, and forming a semiconductor structure 234 on the patterned stop layer 230. The semiconductor structure 234 may include a different material than the patterned stop layer 230, with a second side S2 thereof facing the patterned stop layer 230.

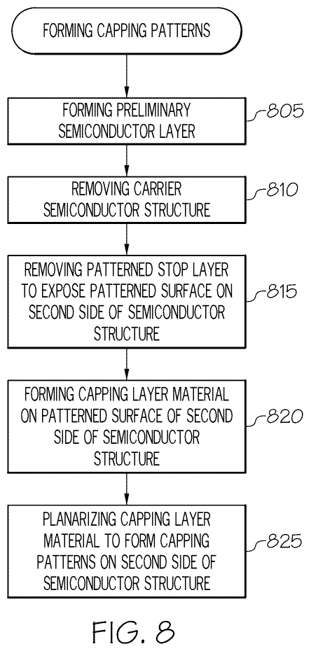

FIGS. 3A, 3B, 3C, 3D, and 3E are cross-sectional views and FIG. 8 is a flowchart illustrating a method of forming capping patterns 338 for fabricating self-aligned backside contact structures 106 according to some embodiments.

As shown in FIG. 3A, a preliminary semiconductor layer 336 may be formed on a first side S1 (or frontside) of the semiconductor structure 234 (at block 805 in FIG. 8). The semiconductor structure 234 may be turned over (inverted in the third direction D3) so that the carrier semiconductor structure 228 faces upwardly. For example, the preliminary semiconductor layer 336 may be below the first side S1 (or frontside) of the semiconductor structure 234.

As shown in FIG. 3B, a backside thinning operation may be performed such that (portions of) the carrier semiconductor structure 228 on the patterned stop layer 230 are thinned or otherwise removed until a back surface of the patterned stop layer 230 is exposed (at block 810 in FIG. 8). As used herein, the term “exposed” may be used to describe relationships between elements and/or certain intermediate processes in fabricating the integrated circuit device 100, but may not necessarily require exposure of the particular region, layer, structure or other element in the context of the completed device.

As shown in FIG. 3C, the patterned stop layer 230 may be removed or stripped (for example, using a selective etching process) to expose a patterned surface 234S on the second side S2 of the semiconductor structure 234 (at block 815 in FIG. 8). The patterned surface 234S of the second side S2 of the semiconductor structure 234 may thereby include a plurality of trenches (or recesses) 234T therein, based on and corresponding to the trenches 230T in the patterned stop layer 230. The trenches (or recesses) 234T of the patterned surface 234S of the second side (or backside) S2 of the semiconductor structure 234 may vertically overlap (in the third direction D3) with the channel structures 104 on the first side S1 (or frontside) of the semiconductor structure 234, which will be described below (referring to FIG. 4A).

As shown in FIG. 3D, a capping layer material 338L may be deposited or otherwise formed on the patterned surface 234S of the second side S2 of the semiconductor structure 234 (at block 820 in FIG. 8). The capping layer material 338L may include (e.g., may be) silicon nitride (SiN), silicon oxide (SiO), and/or other material that may be selectively etched with respect to materials of the semiconductor structure 234 and/or (subsequently formed) mask patterns or the substrate 120. The capping layer material 338L may conformally extend on the patterned surface 234S of the second side S2 of the semiconductor structure 234, (at least partially) filling the trenches (or recesses) 234T therein.

As shown in FIG. 3E, a planarization process (such as a chemical mechanical polishing (CMP) process) may be performed to expose the surfaces of the semiconductor structure 234 (at block 825 in FIG. 8). Portions of the capping layer material 338L may remain in the trenches 234T in the second side (or backside) S2 of the semiconductor structure 234 to provide capping patterns 338.

In particular embodiments, a backside thinning step may be performed in FIG. 3B to reveal a back surface of an SiGe patterned stop layer 230, and a patterned Si surface may be revealed after stripping or removal of the SiGe patterned stop layer 230 in FIG. 3C. Trenches or other recesses in the patterned Si surface (provided by removal of the SiGe patterned stop layer 230) may be filled with a SiN capping layer material 338L in FIG. 3D, followed by a CMP process using the Si surface as a stop layer in FIG. 3E, forming (SiN) capping patterns 338.

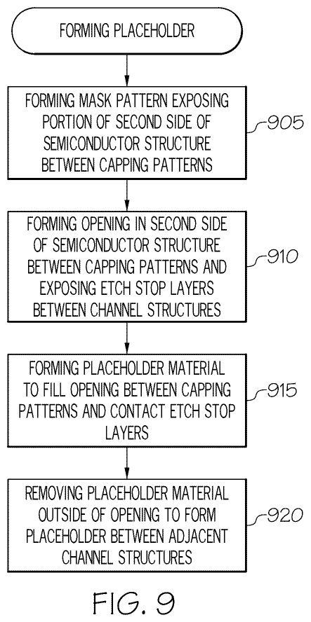

FIGS. 4A, 4B, 4C, 4D, 4E, and 4F are cross-sectional views and FIG. 9 is a flowchart illustrating a method of forming placeholders 442 for fabricating self-aligned backside contact structures 106 according to some embodiments.

As shown in FIG. 4A, front-end-of-line (FEOL) processes may be performed (including fabrication of the gate structures 102, channel structures 104, shallow trench isolation (STI) or other device isolation patterns (or layers) 114, well regions, source/drain regions 108, and metal interconnection layers or structures) in (on) the preliminary semiconductor layer 336. The preliminary semiconductor layer 336 may further include the lower gate insulating spacers 112, the upper gate insulating spacers 116, and the etch stop layers 110. The upper structure 118 may be disposed on the gate structures 102 and the isolation patterns 114. In some embodiments, the preliminary semiconductor layer 336 including the elements described above may be bonded to (the first side S1 of) the semiconductor structure 234 in the process illustrated in FIG. 3A. In some embodiments, the elements of the preliminary semiconductor layer 336 described above may be formed in (on) the preliminary semiconductor layer 336 after the preliminary semiconductor layer 336 is formed on (e.g., bonded to) (the first side S1 of) the semiconductor structure 234 without such elements therein.

As shown in FIG. 4A, the channel structures 104 may be formed spaced apart in the first direction D1 on the first side S1 of the semiconductor structure 234 that is opposite to the second side S2 (in the third direction D3). The channel structures 104 on the first side S1 of the semiconductor structure 234 may align or overlap (along a direction perpendicular to the semiconductor structure 234 (e.g., the third direction D3), also referred to herein as vertical overlap) the capping patterns 338 on the second side (or backside) S2 of the semiconductor structure 234, respectively, which may correspond to (may be previously) surfaces 230S of the patterned stop layer 230 that extend between the (adjacent) trenches 230T (referring to FIG. 2E). For example, opposing side surfaces of the channel structures 104 (in the first direction D1) on the frontside S1 may be (substantially) aligned (along a direction perpendicular to the semiconductor structure 234 (e.g., the third direction D3), also referred to herein as vertically aligned) with opposing sidewalls of the capping patterns 338 (in the first direction D1), respectively, which may be previously opposing sidewalls of the patterned stop layer 230 (in the first direction D1) between (adjacent) the trenches 230T therein (referring to FIG. 2E). Since the capping patterns 338 are formed early in the fabrication process based on the patterned stop layer 230, the capping patterns 338 may have a high overlay value with the channel structures 104. The capping patterns 338 may allow for forming backside contact structures 106 by using placeholders 442 (which are replaced with the backside contact structures 106) that are self-aligned based on the capping patterns 338, such that the backside contact structures 106 contact the source/drain regions 108 via a self-aligned manner, as described below.

Still referring to FIG. 4A, a hard mask layer 440 may be formed on the capping patterns 338 (on the second side S2 of the semiconductor structure 234). The hard mask layer 440 may include (may be formed of) a material (for example, an oxide-based material) that differs in material composition from (and thus has an etch selectivity to) the material of the capping patterns 338 (for example, a nitride-based material). As shown in FIG. 4B, the hard mask layer 440 may be patterned (e.g., lithographically) to define mask openings (or recesses) 4400 therein (at block 905 in FIG. 9). The mask openings 4400 in the patterned hard mask layer 440 may expose portions of the second side (or backside) S2 of the semiconductor structure 234 that are between adjacent capping patterns 338 (in the first direction D1). As shown in FIG. 4C, the exposed portions of the second side (or backside) S2 of the semiconductor structure 234 may be selectively etched using the patterned hard mask layer 440 as an etching mask to form openings 234o in the second side S2 of the semiconductor structure 234 that expose at least one of the etch stop layers 110 on the source/drain regions 108 between adjacent channel structures 104 (at block 910 in FIG. 9). Some of the etch stop layers 110 may not be exposed by the openings 234o. The etching process may be selective to the material of the capping patterns 338, such that the openings 234o (and the etch stop layers 110 exposed thereby) are aligned by and extend between adjacent capping patterns 338 (and between the channel structures 104 that vertically overlap the adjacent capping patterns 338) and expose the etch stop layers 110.

As shown in FIG. 4D, a placeholder material 442L may be formed (deposited and/or epitaxially grown) to (at least partially) fill the openings 234o in the portions of the second side (or the backside) S2 of the semiconductor structure 234 (and the corresponding mask openings 4400 in the patterned hard mask layer 440) such as the placeholder material 442L contacts the etch stop layers 110 (which may be portions of the source/drain regions 108) between adjacent channel structures 104 (at block 915 in FIG. 9). As shown in FIG. 4E, the portions of the placeholder material 442L that extends outside the openings 234o (as well as the patterned hard mask layer 440 and the capping patterns 338) may be removed such that portions of the placeholder material 442L that contact the etch stop layers 110 between adjacent channel structures 104 remain as source/drain placeholder elements 442 (at block 920 in FIG. 9). The source/drain placeholder elements 442 may be referred to as placeholders 442. For example, the portions of the placeholder material 442L outside the openings 234o, the patterned hard mask layer 440, and the capping patterns 338 may be removed by chemical mechanical polishing process using the semiconductor structure 234 as a stop layer. As shown in FIG. 4F, the semiconductor structure 234 may be selectively removed from the second side (or the backside) S2 (for example, using a wet cleaning process that is selective to the material of the semiconductor structure 234) to expose the etch stop layer 110 (and the gate structure 102, the source/drain regions 108, and/or the preliminary semiconductor layer 336 and/or the lower gate insulating spacers 112) between adjacent channel structures 104, and such that the placeholders 442 remain in contact with the etch stop layer 110. In some embodiments, each of the source/drain regions 108 may have the etch stop layer 110 thereon. Some of the etch stop layers 110 may be in contact with the placeholders 442. Some of the etch stop layers 110 may not be in contact with the placeholders 442. For example, the placeholders 442 may be disposed on (e.g., may overlap in the third direction D3) some of the source/drain regions 108. In some embodiments, at least one of the source/drain regions 108 may not overlap with the placeholders 442 in the third direction D3.

In particular embodiments, using a (self-aligned SiN) capping pattern 338, a backside contact structure 106 that extends through the etch stop layer 110 and contacts a source/drain region 108 between adjacent channel structures 104 can be more easily and more accurately formed (via a self-aligned manner). However, as the Si or other semiconductor structure 234 may be replaced with a (dielectric) substrate 120 (e.g., an oxide substrate, such as SiO₂), a placeholder 442 is formed first. An etch process may be carried out between the nanosheets or other channel structures 104, and an etched space may be filled with silicon nitride followed by CMP to form the placeholder 442.

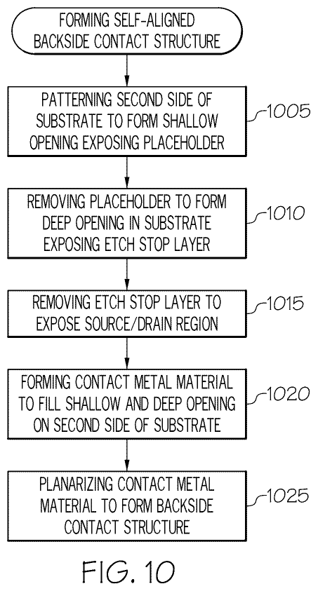

FIGS. 5A, 5B, 5C, 5D, 5E, 5F, and 5G are cross-sectional views and FIG. 10 is a flowchart illustrating a method of forming self-aligned backside contact structures 106 using the placeholders 442 according to some embodiments.

As shown in FIG. 5A, a dielectric or insulating material (e.g., an oxide material) may be formed on the transistor structures TS (including the gate structures 102, the channel structures 104, and the source/drain regions 108), the etch stop layer 110, and the placeholders 442 to form the substrate 120. The substrate 120 may have the first side (or the frontside) S1 and the second side (or the backside) S2. The frontside S1 may face the transistor structure TS, and the backside S2 may be opposite to the frontside S1 in the third direction D3.

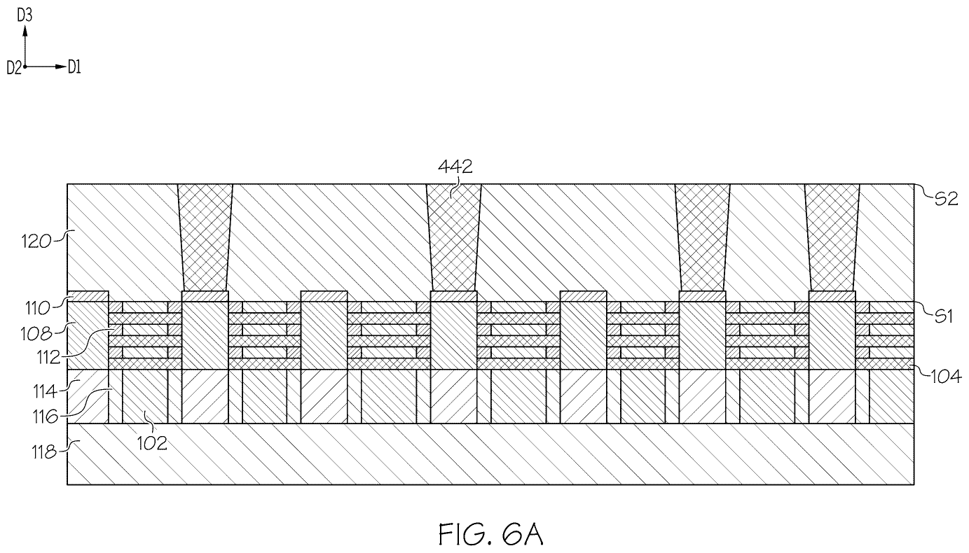

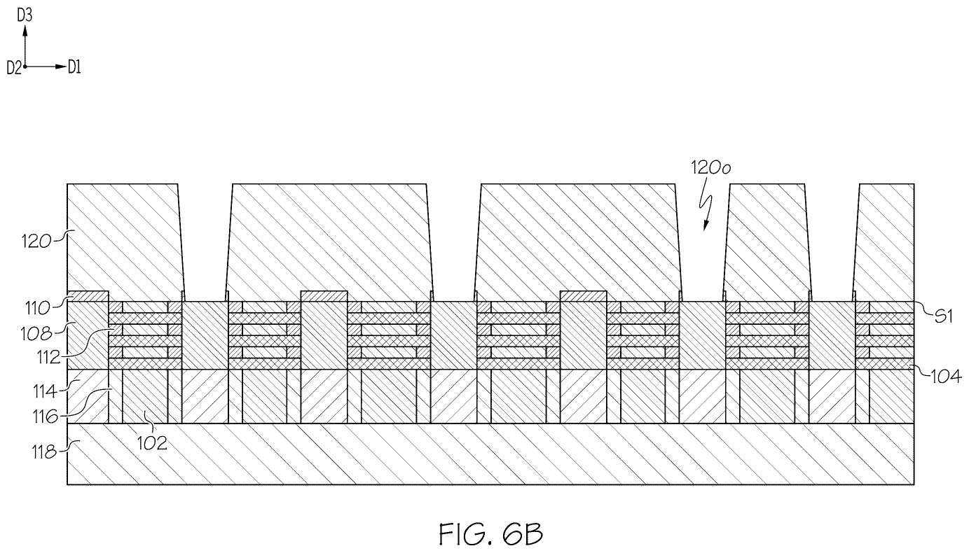

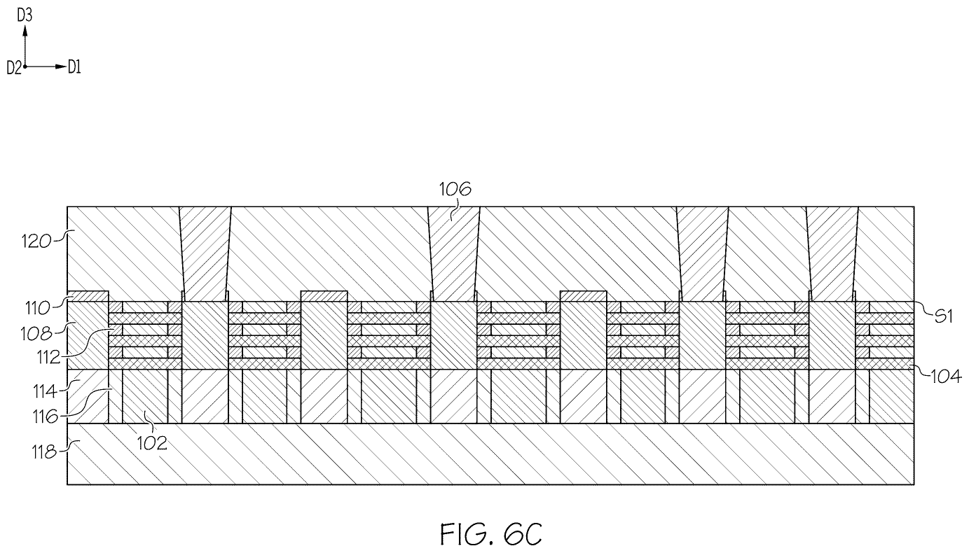

As shown in FIG. 5B, the backside S2 of the substrate 120 may be patterned (e.g., lithographically) to define first or shallower openings 120l therein that expose the placeholders 442 (at block 1005 in FIG. 10). The shallower openings 120l in the substrate 120 (which expose the placeholders 442) may define the shape of a lower portion of the backside contact structure 106 (also referred to as the lower contact structure 106l) that is formed in subsequent operations. As shown in FIG. 5C, the placeholders 442 may be selectively removed, for example, using a selective wet etching process, thereby forming second or deeper openings 120u in the substrate 120 that expose the etch stop layer 110 between adjacent channel structures 104 (at block 1010 in FIG. 10). The etching process may be selective to the material of the etch stop layer 110. As shown in FIG. 5D, the etch stop layers 110 exposed by the deeper openings 120u may be selectively (at least partially) removed by an etching process to expose at least portions of the source/drain regions 108. The etching process may be selective to the material of the source/drain regions 108. For example, the deeper openings 120u may further extend through the etch stop layers 110 to expose the source/drain regions 108 (at block 1015 in FIG. 10). The deeper openings 120u in the substrate 120 (which expose the source/drain regions 108) may define the shape of an upper portion of the backside contact structure 106 (also referred to as an upper contact structure 106u) that is formed in subsequent operations. Respective sidewalls of the deeper openings 120u may have different slopes than respective sidewalls of the shallower openings 120l. In the example of FIGS. 5D, a step difference ST may be defined between the respective sidewalls of the deeper opening 120u (formed by removing the placeholders 442 and the etch stop layer 110) and the shallower opening 120l (formed by patterning the substrate 120 to expose the placeholders 442). The cross-sectional profiles of the shallower opening 120l and the deeper opening 120u may vary. For example, while illustrated as being narrower than the shallower openings 120l, the deeper openings 120u may be wider (along a direction (e.g., the first direction D1 and/or the second direction D2) parallel to the backside S2 of the substrate 120) than the shallower openings 120l in some embodiments. In some embodiments, the sidewalls of the shallower opening 120l and the deeper opening 120u may have the same slope (e.g., slopes angled at the same angle) and may not have a step difference ST therebetween (which will be described below referring to FIGS. 6A, 6B, and 6C).

As shown in FIG. 5E, a contact metal material may be formed (deposited) on the second side (or backside) S2 of the substrate 120, (at least partially) filling the shallow and deeper openings 120l, 120u therein to contact the source/drain regions 108 exposed by the openings (at block 1020 in FIG. 10). As shown in FIG. 5F, a planarization process (e.g., CMP) using the material of the substrate 120 (e.g., the oxide material) as a stop layer may be performed to form the backside contact structure 106 (at block 1025 in FIG. 10). Some of the source/drain regions 108 may not contact (may not overlap in the third direction D3) with the backside contact structure 106.

As shown in FIG. 5G, the BSPDN structure 122 (including the backside power rail 126, the backside insulator 124, and associated conductive plugs) may be formed by patterning the backside insulator 124 and forming the backside power rail 126 therein to arrive at the integrated circuit device 100 shown in FIGS. 1A, 1B, and 1C, with the backside contact structure 106 providing electrical connection between the source/drain region 108 and the BSPDN structure 122.

As noted with reference to FIGS. 1A, 1B, and 1C, the backside contact structure 106 may include a lower contact structure 106l and an upper contact structure 106u, where the upper contact structure 106u contacts the source/drain region 108 and extends between the lower contact structure 106l and the source/drain region 108. Because the upper contact structure 106u and the lower contact structure 106l of the backside contact structure 106 are formed using separate fabrication operations or processing steps, respective side surfaces 106us, 106ls of the upper and lower contact structures 106u and 106l may be formed at different angles, and thus, may have different slopes. For example, a side surface 106us of the upper contact structure 106u may have a first slope that is less than a second slope of the side surface 106ls of the lower contact structure 106l, or vice versa. Also, because the upper contact structure 106u and the lower contact structure 106l are formed in separate fabrication operations or processing steps, the respective side surfaces 106us, 106ls of the upper and lower contact structures 106u and 106l may not be aligned, resulting in at least one step difference ST between the respective side surfaces 106us, 106ls of the upper and lower contact structures 106u and 106l. That is, since the placeholders 442 are selectively formed at (on) (some of) the source/drain regions 108 only, and as the placeholders 442 are formed with a unique shape, the upper portions of the backside contact structures 106 (the upper contact structure 106u) may be formed with shapes that correspond to the shape of the placeholders 442 (and the shape of at least a portion of the etch stop layer 110), while the lower portions (the lower contact structure 106l) of the backside contact structures 106 may be formed with different shapes that correspond to the shallower opening 120l in the substrate 120.

FIGS. 6A, 6B, and 6C are cross-sectional views illustrating a method of forming self- aligned backside contact structures 106 using the placeholder elements 442 according to some embodiments.

FIGS. 6A, 6B, and 6C may illustrate the processes after the intermediate structure of the integrated circuit device 100 illustrated in FIG. 4F. Referring to FIG. 6A, a dielectric or insulating material (e.g., an oxide material) may be formed on the transistor structures TS (including the gate structures 102, the channel structures 104, and the source/drain regions 108), the etch stop layer 110, and the placeholders 442 to from a substrate 120. In some embodiments, the dielectric or insulating material may be formed on (e.g., may be formed to cover or overlap with in the third direction D3) upper surfaces of the placeholders 442. Then, the dielectric or insulating material may be planarized (by, for example, a CMP process) to expose the upper surfaces of the placeholders 442. The substrate 120 may have the first side (or the frontside) S1 and the second side (or the backside) S2. The frontside S1 may face the transistor structure TS, and the backside S2 may be opposite to the frontside S1 in the third direction D3. Still referring to FIG. 6A, upper surfaces of the placeholders 442 may be coplanar with the second side S2 of the substrate 120. In some embodiments, the upper surfaces of the placeholders 442 may be farther than the second side S2 of the substrate 120 from the first side S1 of the substrate 120 in the third direction D3. As shown in FIG. 6B, the placeholders 442 and the etch stop layers 110 therebelow may be selectively removed to form openings 120o of the substrate 120, and the openings 120o may expose the source/drain regions 108. In some embodiments, each sidewall of the openings 120o may extend continuously without a step difference. For example, each sidewall of the openings 120o may have a single or (substantially) uniform slope. Referring to FIG. 6C, the backside contact structures 106 may be disposed in the openings 120o of the substrate 120. Each sidewall of the backside contact structure 106 may have a single or (substantially) uniform slope. For example, the sidewalls of the backside contact structure 106 may extend continuously without a step difference.

Unless otherwise defined, all terms used herein have the same meaning as commonly understood by one of ordinary skill in the art. Further, all terms should be interpreted as having a meaning that is consistent with their meaning in the context of the relevant art and this disclosure and will not be interpreted in an idealized or overly formal sense unless expressly so defined herein.

In the description above, each example embodiment is described with reference to regions of particular conductivity types. It will be appreciated that opposite conductivity type devices may be formed by simply reversing the conductivity of the n-type and p-type layers in each of the above embodiments. Thus, it will be appreciated that the present invention covers both n-channel and p-channel devices for each different device structure.

The terminology used herein is for the purpose of describing particular embodiments only and is not intended to be limiting of embodiments. The singular forms “a,” “an,” and “the” are intended to include the plural forms as well, unless the context clearly indicates otherwise. The terms “comprises,” “comprising,” “includes” and/or “including” specify the presence of stated features, steps, operations, elements and/or components, but do not preclude the presence or addition of one or more other features, steps, operations, elements, components and/or groups thereof.

It will be understood that, although the terms “first,” “second,” etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terms “surround” or “cover” or “fill” as may be used herein may not require completely surrounding or covering or filling the described elements or layers, but may, for example, refer to partially surrounding or covering or filling the described elements or layers. Components or layers described with reference to “overlap” in a particular direction may be at least partially obstructed by one another when viewed along a line extending in the particular direction or in a plane perpendicular to the particular direction.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. The term “connected” may include physical and/or electrical connection.

Spatially relative terms such as “below” or “above” or “upper” or “lower” or “top” or “bottom” or “side” may be used herein to describe a relationship of one element, layer or region to another element, layer or region based on a frame of reference (e.g., a substrate), as illustrated in the figures. It will be understood that these terms are intended to encompass different orientations of the device in addition to the orientation depicted in the figures.

Example embodiments are described herein with reference to the accompanying drawings, which may include cross-section illustrations that are schematic illustrations of idealized embodiments (and intermediate structures). Many different forms and embodiments are possible without deviating from the teachings of this disclosure. Accordingly, the disclosure should not be construed as limited to the example embodiments set forth herein. As such, it will be understood by those of ordinary skill in the art that various changes in form and details may be made therein without departing from the spirit and scope as defined herein. In the drawings, the sizes and relative sizes of layers and regions may be exaggerated for clarity. Additionally, variations from the shapes of the illustrations as a result, for example, of manufacturing techniques and/or tolerances, are to be expected.

Embodiments of the invention are also described with reference to a fabrication operations and flowchart diagrams. It will be appreciated that the steps shown in the fabrication operations and flowchart diagrams need not be performed in the order shown.

The above-disclosed subject matter is to be considered illustrative, and not restrictive, and the appended claims are intended to cover all such modifications, enhancements, and other embodiments, which fall within the scope of the disclosure. Thus, to the maximum extent allowed by law, the scope is to be determined by the broadest permissible interpretation of the following claims and their equivalents, and shall not be restricted or limited by the foregoing

1. A semiconductor device comprising:
a substrate;
source/drain regions with channel structures extending therebetween at a first side of the substrate, wherein the source/drain regions are spaced apart from each other in a first direction by the channel structures; and
a backside contact structure extending into a second side of the substrate that is opposite the first side of the substrate, wherein the backside contact structure is electrically connected to at least one of the source/drain regions,
wherein the backside contact structure comprises a lower contact structure and an upper contact structure between the lower contact structure and the at least one of the source/drain regions, and respective side surfaces of the upper contact structure and the lower contact structure have different slopes,
wherein the upper contact structure has a first width adjacent the at least one of the source/drain regions and a second width adjacent the lower contact structure, and
wherein the second width is greater than the first width.

2. The semiconductor device of claim 1, wherein the respective side surfaces of the upper contact structure and the lower contact structure define a step difference therebetween.

3. The semiconductor device of claim 2, wherein a first slope of the side surface of the upper contact structure is less than a second slope of the side surface of the lower contact structure.

4. The semiconductor device of claim 2, wherein a width of the upper contact structure continuously decreases from the second width to the first width as the upper contact structure extends from the lower contact structure to the at least one of the source/drain regions.

5. The semiconductor device of claim 4, further comprising:
etch stop layers at the first side of the substrate, wherein the etch stop layers are on the source/drain regions, respectively,
wherein the backside contact structure extends through at least one of the etch stop layers to contact the at least one of the source/drain regions.

6. The semiconductor device of claim 5, wherein the etch stop layers have an etch selectivity to the source/drain regions, and
wherein the backside contact structure does not overlap at least one of the etch stop layers in a second direction that is perpendicular to the first direction.

7. The semiconductor device of claim 4, further comprising:
a backside power distribution network structure on a lower surface of the substrate,
wherein the lower surface of the substrate is at the second side of the substrate, and
wherein the backside contact structure electrically connects the backside power distribution network structure to the at least one of the source/drain regions.

8. A method of fabricating a semiconductor device, the method comprising:
forming capping patterns that are spaced apart from each other in a first direction at a first side of a semiconductor structure;
forming channel structures and source/drain regions therebetween that are spaced apart from each other in the first direction at a second side of the semiconductor structure that is opposite the first side of the semiconductor structure in a second direction, wherein the capping patterns overlap the channel structures in the second direction, respectively; and
forming a backside contact structure that is electrically connected to at least one of the source/drain regions and is aligned to overlap the at least one of the source/drain regions in the second direction based on the capping patterns.

9. The method of claim 8, wherein opposing side surfaces of the capping patterns are substantially aligned with opposing side surfaces of the channel structures, respectively, in the second direction.

10. The method of claim 9, wherein forming the backside contact structure comprises:
forming a placeholder on the at least one of the source/drain regions, wherein the placeholder extends into the second side of the semiconductor structure between adjacent ones of the capping patterns.

11. The method of claim 10, wherein forming the placeholder comprises:
forming an opening between the adjacent ones of the capping patterns in the semiconductor structure that overlaps with the at least one of the source/drain regions in the second direction; and
forming the placeholder in the opening, and
wherein at least some of the source/drain regions are free of overlap with respective placeholders in the second direction.

12. The method of claim 10, wherein forming the backside contact structure further comprises:
removing the semiconductor structure and the capping patterns therein to expose the placeholder;
forming a substrate on the placeholder, the channel structures, and the source/drain regions, wherein the channel structures and the source/drain regions are at a first side of the substrate;
patterning a second side of the substrate that is opposite the first side of the substrate in the second direction to form a first opening therein that exposes the placeholder; and
replacing the placeholder with the backside contact structure.

13. The method of claim 12, wherein replacing the placeholder comprises:
removing the placeholder to form a second opening in the substrate that is coupled to the first opening; and
forming the backside contact structure in the first opening and the second opening.

14. The method of claim 13, wherein respective side surfaces of the first opening and the second opening have different slopes, and wherein the backside contact structure comprises a lower contact structure in the first opening and an upper contact structure in the second opening between the lower contact structure and the at least one of the source/drain regions.

15. The method of claim 14, wherein the respective side surfaces of the first opening and the second opening define a step difference therebetween.

16. (canceled)

17. The method of claim 8, wherein forming the capping patterns comprises:
patterning a stop layer material that is different from a material of the semiconductor structure to define a patterned stop layer having plurality of trenches therein that are spaced apart in the first direction;
forming the semiconductor structure on the patterned stop layer;
removing the patterned stop layer to expose a patterned surface at the first side of the semiconductor structure; and
forming the capping patterns in the patterned surface at the first side of the semiconductor structure.

18. A method of fabricating a semiconductor device, the method comprising:
patterning a stop layer material to define a patterned stop layer having plurality of first trenches therein that are spaced apart in a first direction;
forming a semiconductor structure on the patterned stop layer, the semiconductor structure comprising a different material than the patterned stop layer and having a first side thereof facing the patterned stop layer;
removing the patterned stop layer to expose a patterned surface having a plurality of second trenches therein on the first side of the semiconductor structure; and
forming source/drain regions and channel structures extending therebetween at a second side of the semiconductor structure that is opposite the first side, wherein the channel structures vertically overlap the second trenches in the patterned surface on the first side of the semiconductor structure, respectively.

19. The method of claim 18, wherein opposing side surfaces of the channel structures are substantially aligned with opposing sidewalls of the second trenches in the patterned surface, respectively, in a second direction that is perpendicular to the first direction.

20. The method of claim 19, further comprising:
forming capping patterns in the second trenches in the patterned surface at the first side of the semiconductor structure, wherein opposing side surfaces of the capping patterns are substantially aligned with opposing side surfaces of the channel structures, respectively; and
forming a backside contact structure that contacts at least one of the source/drain regions and is aligned based on adjacent ones of the capping patterns.

21. The method of claim 20, wherein forming the backside contact structure comprises:
forming a placeholder on the at least one of the source/drain regions, wherein the placeholder extends between the adjacent ones of the capping patterns.

22-27. (canceled)
